(19) United States
(12) Patent Application Publication
(10) Pub. No.: US 2024/0244852 A1
(43) Pub. Date: Jul. 18, 2024

(54) MEMORY DEVICE

(71) Applicant: Kioxia Corporation, Tokyo (JP)

(72) Inventors: Yuki NAKACHI, Kuwana (JP); Yuya SAEKI, Yokkaichi (JP)

(73) Assignee: Kioxia Corporation, Tokyo (JP)

(21) Appl. No.: 18/538,551

(22) Filed: Dec. 13, 2023

(30) Foreign Application Priority Data
Jan. 13, 2023 (JP) 2023-004015

(51) Int. Cl. H10B 80/00; H01L 23/00; H01L 25/00; H01L 25/065; H01L 25/18

(52) U.S. Cl. CPC H10B 80/00; H01L 24/08; H01L 24/80; H01L 25/0657; H01L 25/18; H01L 25/50; H01L 2224/08145; H01L 2224/80006; H01L 2224/80895; H01L 2224/80896; H01L 2924/1431; H01L 2924/14511

(57) ABSTRACT

A memory device includes a first conductive layer; a second conductive layer arranged with the first conductive layer in a first direction in a first region; third conductive layers arranged in the first region and mutually separated in the first direction; a conductor extending in the first direction and intersecting extensions of the third conductive layers in a second region; and a memory pillar having portions intersecting the third conductive layers and functioning as memory cells. The second conductive layer includes a first portion extending in a plane and in contact with the memory pillar and a second portion arranged on a surface of the first portion on a side of the first conductive layer to protrude with respect to the first portion. The first conductive layer includes third and fourth portions in contact with the second portion and the conductor, respectively.

### CROSS-REFERENCE TO RELATED APPLICATIONS

This application is based upon and claims the benefit of priority from Japanese Patent Application No. 2023-004015, filed Jan. 13, 2023, the entire contents of which are incorporated herein by reference.

### FIELD

Embodiments described herein relate generally to a memory device.

### BACKGROUND

A NAND flash memory has been known as a memory device capable of storing data in a nonvolatile manner. In order to enhance integration and increase the capacity, a three-dimensional memory structure has been adopted in a memory device as represented by a NAND flash memory.

### BRIEF DESCRIPTION OF THE DRAWINGS

FIG. 1 is a block diagram showing an exemplary configuration of a memory system that includes a memory device according to a first embodiment.

FIG. 2 is a circuit diagram showing an exemplary circuit configuration of a memory cell array in the memory device according to the first embodiment.

FIG. 3 is a perspective overview of a bonded structure in the memory device according to the first embodiment.

FIG. 4 is a plan view showing an exemplary planar layout of the memory device according to the first embodiment.

FIG. 5 is a cross-sectional view taken along line V-V of FIG. 4, showing an exemplary cross-sectional structure of the memory device according to the first embodiment.

FIG. 6 is a plan view showing an exemplary planar layout of wall structures and connection wirings between the core region and peripheral circuit region in the memory device according to the first embodiment.

FIG. 7 is a plan view showing an exemplary planar layout of a block region in the memory device according to the first embodiment.

FIG. 8 is a cross-sectional view taken along line VIII-VIII of FIG. 7, showing an exemplary cross-sectional structure of the block region in the memory device according to the first embodiment.

FIG. 9 is a cross-sectional view taken along line IX-IX of FIG. 8, showing an exemplary cross-sectional structure of a memory pillar in the memory device according to the first embodiment.

FIG. 10 is a cross-sectional view showing an exemplary cross-sectional structure of bonding pads in the memory device according to the first embodiment.

FIG. 11 is a cross-sectional view showing an exemplary cross-sectional structure of the memory device according to the first embodiment in the course of manufacturing.

FIG. 12 is a cross-sectional view showing an exemplary cross-sectional structure of the memory device according to the first embodiment in the course of manufacturing.

FIG. 13 is a cross-sectional view showing an exemplary cross-sectional structure of the memory device according to the first embodiment in the course of manufacturing.

FIG. 14 is a cross-sectional view showing an exemplary cross-sectional structure of the memory device according to the first embodiment in the course of manufacturing.

FIG. 15 is a cross-sectional view showing an exemplary cross-sectional structure of the memory device according to the first embodiment in the course of manufacturing.

FIG. 16 is a cross-sectional view showing an exemplary cross-sectional structure of the memory device according to the first embodiment in the course of manufacturing.

FIG. 17 is a cross-sectional view showing an exemplary cross-sectional structure of the memory device according to the first embodiment in the course of manufacturing.

FIG. 18 is a cross-sectional view showing an exemplary cross-sectional structure of the memory device according to the first embodiment in the course of manufacturing.

FIG. 19 is a cross-sectional view showing an exemplary cross-sectional structure of the memory device according to the first embodiment in the course of manufacturing.

FIG. 20 is a cross-sectional view showing an exemplary cross-sectional structure of a memory device according to a modification of the first embodiment.

FIG. 21 is a cross-sectional view showing an exemplary cross-sectional structure of the memory device according to the modification of the first embodiment in the course of manufacturing.

FIG. 22 is a cross-sectional view showing an exemplary cross-sectional structure of the memory device according to the modification of the first embodiment in the course of manufacturing.

FIG. 23 is a cross-sectional view showing an exemplary cross-sectional structure of a memory device according to a second embodiment.

FIG. 24 is a plan view showing an exemplary planar layout of wall structures and connection wirings between the core region and peripheral circuit region in the memory device according to the second embodiment.

FIG. 25 is a cross-sectional view showing an exemplary cross-sectional structure of the memory device according to the second embodiment in the course of manufacturing.

FIG. 26 is a cross-sectional view showing an exemplary cross-sectional structure of the memory device according to the second embodiment in the course of manufacturing.

FIG. 27 is a cross-sectional view showing an exemplary cross-sectional structure of the memory device according to the second embodiment in the course of manufacturing.

FIG. 28 is a cross-sectional view showing an exemplary cross-sectional structure of the memory device according to the second embodiment in the course of manufacturing.

FIG. 29 is a cross-sectional view showing an exemplary cross-sectional structure of the memory device according to a modification of the second embodiment.

FIG. 30 is a cross-sectional view showing an exemplary cross-sectional structure of the memory device according to the modification of the second embodiment in the course of manufacturing.

FIG. 31 is a cross-sectional view showing an exemplary cross-sectional structure of the memory device according to the modification of the second embodiment in the course of manufacturing.

FIG. 32 is a cross-sectional view of an exemplary cross-sectional structure of a memory device according to a third embodiment.

FIG. 33 is a cross-sectional view showing an exemplary cross-sectional structure of a memory cell array in the memory device according to the third embodiment.

FIG. 34 is a cross-sectional view of an exemplary pattern of a protruding portion in the memory cell array taken along line XXXIV-XXXIV of FIG. 33 in the memory device according to the third embodiment.

FIG. 35 is a cross-sectional view showing an exemplary cross-sectional structure of the memory device according to the third embodiment in the course of manufacturing.

FIG. 36 is a cross-sectional view showing an exemplary cross-sectional structure of the memory device according to the third embodiment in the course of manufacturing.

FIG. 37 is a cross-sectional view showing an exemplary cross-sectional structure of the memory device according to the third embodiment in the course of manufacturing.

FIG. 38 is a cross-sectional view showing an exemplary cross-sectional structure of the memory device according to the third embodiment in the course of manufacturing.

FIG. 39 is a cross-sectional view showing a first example of a pattern of a protruding portion in a memory cell array of a memory device according to a modification of the third embodiment.

FIG. 40 is a cross-sectional view showing a second example of the pattern of a protruding portion in a memory cell array of a memory device according to the modification of the third embodiment.

FIG. 41 is a cross-sectional view showing a third example of the pattern of a protruding portion in a memory cell array of a memory device according to the modification of the third embodiment.

FIG. 42 is a cross-sectional view showing an exemplary cross-sectional structure of a memory device according to another modification.

### DETAILED DESCRIPTION

In general, according to one embodiment, a memory device includes a first conductive layer; a second conductive layer arranged with the first conductive layer in a first direction in a first region; a plurality of third conductive layers arranged in the first region on a side opposite the first conductive layer in the first direction with respect to the second conductive layer in a mutually separated manner in the first direction; a first conductor extending in the first direction and intersecting extensions of the third conductive layers in a second region different from the first region; and a memory pillar extending in the first direction, of which portions intersecting the third conductive layers function as memory cells. The second conductive layer includes a first portion that extends in a plane intersecting the first direction and is in contact with an end portion of the memory pillar and a second portion that is arranged on a first surface of the first portion on a side of the first conductive layer in the first direction and protrudes with respect to the first portion. The first conductive layer includes a third portion in contact with the second portion in the first region and a fourth portion in contact with an end portion of the first conductor in the second region.

The embodiments will be explained below by referring to the drawings. The dimensions and ratios in the drawings may not always be the same as the actual ones.

In the following explanation, components having basically the same functions and structures will be referred to by the same reference numerals. In the case where components having substantially the same configurations are mutually differentiated, distinguishing characters or numerals may be added at the end of the reference numerals.

### 1. First Embodiment

### 1.1 Configuration

### 1.1.1 Configuration of Memory System

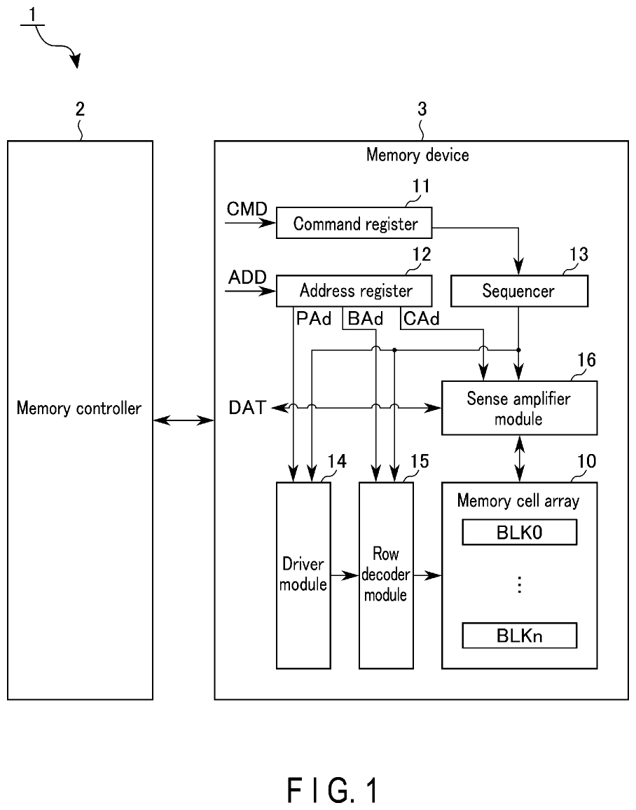

FIG. 1 is a block diagram showing an exemplary configuration of a memory system that includes a memory device according to the first embodiment. The memory system 1 is a storage device adapted for connection with an external host device (not shown). Examples of the memory system 1 include a memory card such as an SD™ card, a universal flash storage (UFS), and a solid state drive (SSD). The memory system 1 includes a memory controller 2 and a memory device 3.

The memory controller 2 is composed of an integrated circuit such as a system-on-a-chip (SoC). The memory controller 2 controls the memory device 3 based on commands from the host device. In particular, the memory controller 2 may write to the memory device 3 the write-requested data requested by the host device. The memory controller 2 may also read from the memory device 3 the read-requested data requested by the host device and send the data to the host device.

The memory device 3 is a nonvolatile memory, such as a NAND flash memory, storing data in a nonvolatile manner.

Communications between the memory controller 2 and the memory device 3 comply with, for example, a single data rate (SDR) interface, a toggle double data rate (DDR) interface, or an open NAND flash interface (ONFI).

### 1.1.2 Configuration of Memory Device

The internal configuration of the memory device according to the first embodiment will be described by referring to the block diagram of FIG. 1. The memory device 3 may include a memory cell array 10, a command register 11, an address register 12, a sequencer 13, a driver module 14, a row decoder module 15, and a sense amplifier module 16.

The memory cell array 10 includes a plurality of blocks BLK0 to BLKn (where n is an integer larger than or equal to 1). The number of blocks BLK in the memory cell array 10 may be one. A block BLK is a set including memory cells, and serves as a data erasable unit. The memory cell array 10 is provided with a plurality of bit lines and word lines. Each memory cell is associated with one bit line and one word line. A more detailed description of the configuration of the memory cell array 10 will be given later.

The command register 11 is adapted to store commands CMD received by the memory device 3 from the memory controller 2. These commands CMD include instructions to instruct the sequencer 13 to implement a read operation, a write operation, an erase operation, and the like.

The address register 12 stores address information ADD received by the memory device 3 from the memory controller 2. The address information ADD may include a block address BAd, a page address PAd, and a column address CAd. The block address BAd, page address PAd, and column address CAd may be used for selection of a block BLK, a word line, and a bit line, respectively.

The sequencer 13 takes total control over the operations of the memory device 3. For instance, the sequencer 13 may control the driver module 14, row decoder module 15, sense amplifier module 16, and the like based on a command CMD stored in the command register 11 to implement a read operation, write operation, and erase operation.

The driver module 14 generates voltages to be used in the read operation, write operation, erase operation, and the like. The driver module 14 applies the generated voltage to a signal line corresponding to a selected word line according to, for example, the page address PAd stored in the address register 12.

The row decoder module 15 refers to the block address BAd stored in the address register 12 to select a corresponding one of the blocks BLK from the memory cell array 10. Then, the row decoder module 15 transfers the voltage applied to the signal line corresponding to the selected word line to this selected word line in the selected block BLK.

In a write operation, the sense amplifier module 16 applies a desired voltage to each bit line in accordance with the write data DAT received from the memory controller 2. In a read operation, the sense amplifier module 16 determines the data stored in a memory cell based on the voltage of the bit line, and transfers the determination result as read data DAT to the memory controller 2.

### 1.1.3 Circuit Configuration of Memory Cell Array

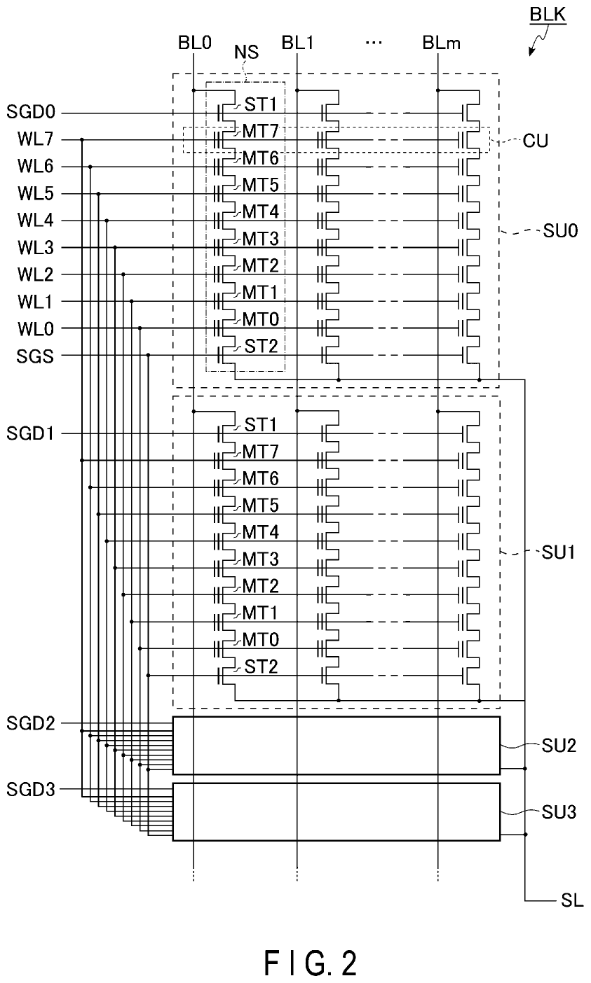

FIG. 2 is a circuit diagram showing an exemplary circuit configuration of a memory cell array in the memory device according to the first embodiment. FIG. 2 shows one of the blocks BLK in the memory cell array 10, where the block BLK contains four string units SU0 to SU3.

Each of the string units SU includes a plurality of NAND strings NS, each associated with one of bit lines BL0 to BLm (where m is an integer greater than or equal to 1). The number of bit lines BL may be one. Each NAND string NS includes memory cell transistors MT0 to MT7 and select transistors ST1 and ST2. A memory cell transistor MT includes a control gate and a charge storage portion, and stores data in a nonvolatile manner. Each of the select transistors ST1 and ST2 is used for selection of a string unit SU in various operations.

In each of the NAND strings NS, memory cell transistors MT0 to MT7 are connected in series with each other. The drain of the select transistor ST1 is coupled to the associated bit line BL. The source of the select transistor ST1 is coupled to one end of the series-coupled memory cell transistors MT0 to MT7. The drain of the select transistor ST2 is coupled to the other end of the memory cell transistors MT0 to MT7 connected in series. The source of the select transistor ST2 is coupled to a source line SL.

Within a block BLK, the control gates of the memory cell transistors MT0 to MT7 are coupled to the word lines WL0 to WL7, respectively. The gates of the select transistors ST1 in the string units SU0 to SU3 are coupled to the select gate lines SGD0 to SGD3, respectively. The gates of the select transistors ST2 are coupled to a select gate line SGS.

Different column addresses are assigned to the bit lines BL0 to BLm. Each bit line BL is shared by NAND strings NS, to which the same column address is assigned among a plurality of blocks BLK. A set including word lines WL0 to WL7 is provided for each block BLK, while the source line SL is shared across a plurality of blocks BLK.

A set including memory cell transistors MT coupled to the common word line WL in a string unit SU may be referred to as a cell unit CU. The storage capacity of a cell unit CU including memory cell transistors MT, which each stores 1-bit data, may be defined as “1-page data”. A cell unit CU may have a storage capacity for 2-page data or more in accordance with the number of bits of the data stored in the memory cell transistor MT.

The circuit configuration of the memory cell array 10 in the memory device 3 according to the first embodiment is not limited to the above-mentioned configuration. For instance, the number of string units SU in a block BLK may be designed to be any number. The number of memory cell transistors MT and select transistors ST1 and ST2 in each NAND string NS may also be designed as appropriate.

### 1.1.4 Bonded Structure in Memory Device

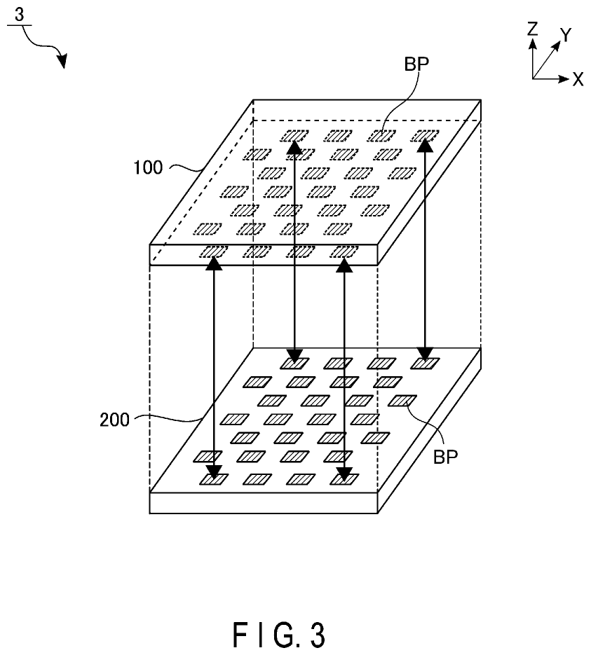

FIG. 3 is a perspective overview of a bonded structure in the memory device according to the first embodiment.

As shown in FIG. 3, the memory device 3 includes a memory chip 100 and a circuit chip 200. The memory chip 100 has a structure corresponding to that of the memory cell array 10. The circuit chip 200 may have a structure corresponding to the command register 11, address register 12, sequencer 13, driver module 14, row decoder module 15, and sense amplifier module 16.

Each of the memory chip 100 and circuit chip 200 includes a plurality of bonding pads BP. The memory device 3 is formed by bonding the memory chip 100 and the circuit chip 200 with the bonding pads BP interposed.

In the following description, a “XY plane” denotes a plane of the memory chip 100 and the circuit chip 200 that are bonded (bonded surface). “X direction” and “Y direction” denote two directions orthogonal to each other in the XY plane. A “Z1 direction” denotes the direction approximately perpendicular to the XY plane and extending from the memory chip 100 to the circuit chip 200, and a “Z2 direction” denotes the direction approximately perpendicular to the XY plane and extending from the circuit chip 200 to the memory chip 100. If the Z1 direction and Z2 direction do not need to be differentiated from each other, they will be referred to as a Z direction.

### 1.1.5 Planar Layout of Memory Device

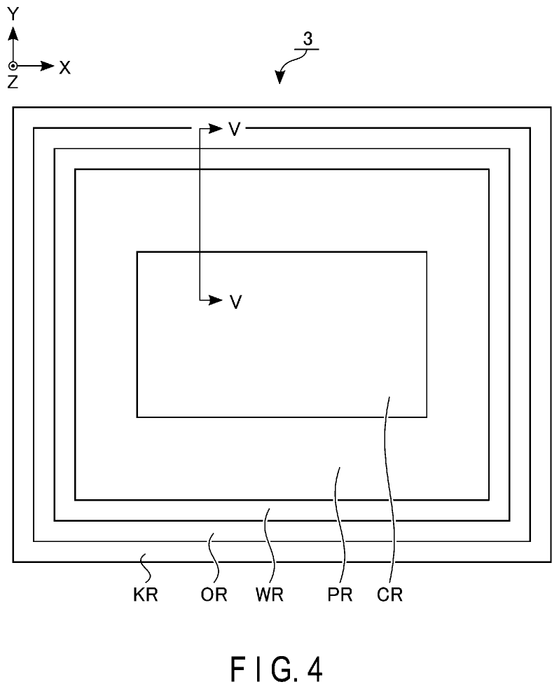

Next, the planar layout of the memory device according to the first embodiment will be described. FIG. 4 is a plan view of an exemplary planar layout of the memory device according to the first embodiment.

As illustrated in FIG. 4, the memory device 3 may be divided into a core region CR, a peripheral circuit region PR, a wall region WR, a circumferential region OR, and a kerf region KR.

The core region CR is a rectangular shape area positioned in the center portion of the memory device 3 when viewed in the Z direction. The memory cell array 10 is arranged in the core region CR of the memory chip 100. The row decoder module 15 and sense amplifier module 16 may be arranged in the core region CR of the circuit chip 200. The number of core regions CR and their shapes can be freely designed.

The peripheral circuit region PR is a rectangular ring area surrounding the outer periphery of the core region CR. For instance, the command register 11, address register 12, sequencer 13, and driver module 14 may be arranged in the peripheral circuit region PR.

The wall region WR is a rectangular ring area surrounding the outer periphery of the peripheral circuit region PR. In the wall region WR, a component for stabilizing the potentials of the power supply line, the well and the like by maintaining the outer periphery of the memory device 3 at a constant potential (ground potential VSS) is provided. The component provided in the wall region WR may have a function of dissipating static charges to a substrate. This can suppress breakage of the circuit owing to the static charges.

The circumferential region OR is a rectangular ring area surrounding the outer periphery of the wall region WR. The circumferential region OR has a function of preventing a crack or the like produced at the edge of the memory device 3 during a dicing process from reaching the inside of the memory device 3. In the dicing process, a wafer on which multiple memory devices 3 are formed is diced into chips.

The kerf region KR is a rectangular ring area surrounding the outer periphery of the circumferential region OR. The kerf region KR includes the edges of the memory device 3. The kerf region KR includes an area between the memory devices 3 before the wafer carrying the memory devices 3 is diced. In the dicing process, cutting is performed in the kerf region KR so that the memory devices 3 on the wafer can be divided as respective chips. For instance, alignment markings or the like may be provided in the kerf region KR to be used for manufacturing of the memory devices 3. The structure in the kerf region KR may be removed during the dicing process.

### 1.1.6 Cross-Sectional Structure of Memory Device

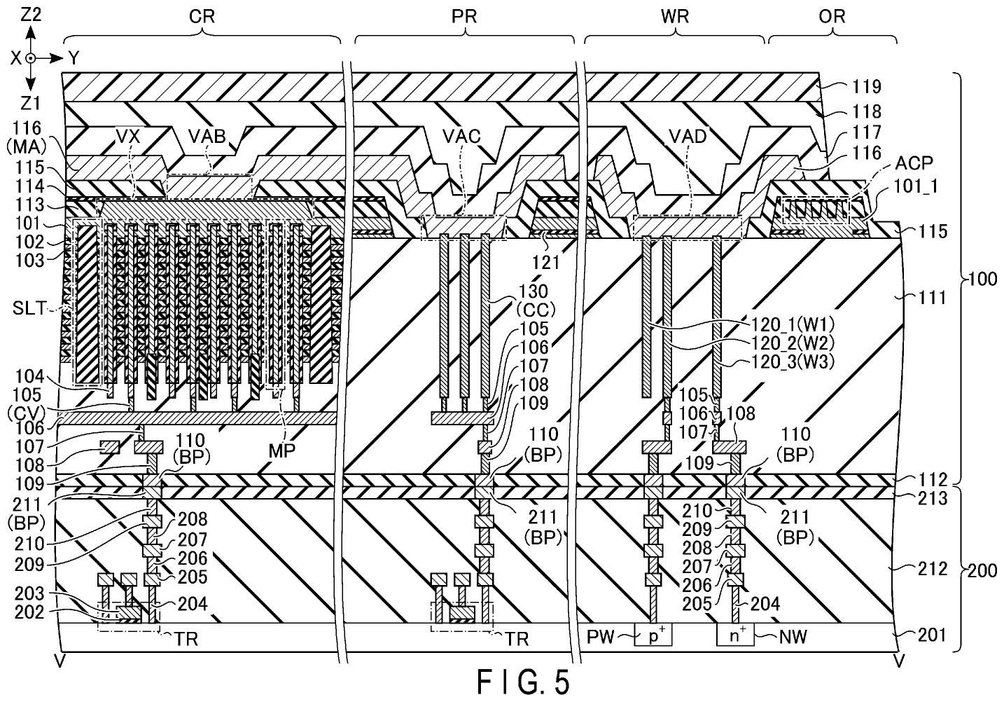

Next, the cross-sectional structure of the memory device according to the first embodiment will be described. FIG. 5 is a cross-sectional view taken along line V-V of FIG. 4, showing an exemplary cross-sectional structure of the memory device according to the first embodiment.

As illustrated in FIG. 5, the memory chip 100 includes a conductive layer 101, insulating layers 102, 111, 112, 113, 114, 115, 117, 118, and 121, interconnect layers 103, 106, 108, and 116, conductors 104, 105, 107, 109, 120, and 130, electrodes 110, a surface protective layer 119, members SLT, and memory pillars MP. The circuit chip 200 includes a semiconductor substrate 201, an N-type impurity diffusion region NW, a P-type impurity diffusion region PW, transistors TR, gate insulating films 202, gate electrodes 203, conductors 204, 206, 208, and 210, interconnect layers 205, 207, and 209, electrodes 211, and insulating layers 212 and 213.

### 1.1.6.1 Cross-Sectional Structure of Memory Chip

First, the structure of the memory chip 100 will be described.

### (Core Region)

The core region CR of the memory chip 100 will be described. In the core region CR of the memory chip 100, a memory cell array 10 and various interconnects connecting the memory cell array 10 to the circuit chip 200 are provided.

The conductive layer 101 expands in the XY plane. The conductive layer 101 in the core region CR serves as a source line SL. The conductive layer 101 may include silicon as a semiconductor. In the core region CR, insulating layers 102 and interconnect layers 103 are alternately stacked on the upper surface of the conductive layer 101 in the Z1 direction. In the example of FIG. 5, ten insulating layers 102 and ten interconnect layers 103 are alternately stacked. In other words, a stack of interconnect layers 103 mutually spaced apart in the Z direction is provided between the circuit chip 200 and conductive layer 101. The interconnect layers 103 extend in the X direction, and serve as word lines WL and select gate lines SGD and SGS. The insulating layer 102 contains silicon oxide (SiO) as an insulating material. The interconnect layers 103 may contain tungsten (W) as a conductive material.

Multiple members SLT are provided in the core region CR. A member SLT may be a plate-shaped insulating member that extends along the XZ plane. The members SLT are aligned in the Y direction, and multiple memory pillars MP are interposed between two adjacent members SLT. A memory pillar MP may be a circular cylinder extending in the Z direction. The detailed structures of the members SLT and memory pillars MP will be described later.

A conductor 104 is arranged on the upper surface of each memory pillar MP in the Z1 direction. The conductor 104 may be shaped into a circular cylinder extending in the Z direction. A conductor 105 is arranged on the upper surface of the conductor 104 in the Z1 direction. The conductor 105 in the core region CR may be shaped into a circular cylinder extending in the Z direction.

Furthermore, interconnect layers 106 are arranged on the upper surface of the conductor 105 in the Z1 direction. In the core region CR, multiple interconnect layers 106 may be aligned in the X direction, each extending in the Y direction. Each of the memory pillars MP is electrically coupled to one of the interconnect layers 106 by way of the conductors 104 and 105. The conductor 105, to which a memory pillar MP is electrically coupled, functions as a contact CV. The interconnect layer 106 to which a memory pillar MP is electrically coupled functions as a bit line BL. The conductor 104 may contain tungsten. The conductor 105 and interconnect layer 106 may contain copper (Cu).

A conductor 107 is arranged on the upper surface of the interconnect layer 106 in the Z1 direction. The conductor 107 in the core region CR may be shaped into a circular cylinder extending in the Z direction. An interconnect layer 108 is arranged on the upper surface of the conductor 107 in the Z1 direction. A conductor 109 is arranged on the upper surface of the interconnect layer 108 in the Z1 direction. The conductor 109 in the core region CR may be shaped into a circular cylinder extending in the Z direction. In the core region CR, an electrode 110 is arranged on the upper surface of the conductor 109 in the Z1 direction. The electrode 110 is electrically coupled to the electrode 211 of the circuit chip 200. The electrodes 110 and 211 serve as bonding pads BP.

The conductors 107 and 109, interconnect layer 108, and electrode 110 may contain copper as a conductive material. The number of interconnect layers to be provided between the interconnect layer 106 and electrode 110 can be freely determined.

The insulating layer 111 is provided in such a manner as to cover the insulating layers 102, interconnect layers 103, memory pillars MP, members SLT, conductors 104, conductors 105, interconnect layers 106, conductors 107, interconnect layers 108, and conductors 109. An insulating layer 112 is provided on the upper surface of the insulating layer 111 in the Z1 direction. Multiple electrodes 110 are arranged at the same level as the insulating layer 112. The insulating layer 112 is in contact with the insulating layer 213 of the circuit chip 200.

The conductive layer 101 includes a protruding portion VX having a certain thickness in the Z2 direction, at a position overlapping the memory pillars MP when viewed in the Z direction. In other words, a protruding portion VX is arranged on the surface of the conductive layer 101 extending along the XY plane on the Z2 direction side in such a manner as to protrude with respect to a portion of the conductive layer 101 extending along the XY plane. The protruding portion VX and the portion of the conductive layer 101 extending along the XY plane are formed as a continuous film. An insulating layer 113 is deposited on the upper surface of the conductive layer 101 in the Z2 direction, where the protruding portion VX is not arranged. The insulating layer 113 has a thickness approximately the same as that of the protruding portion VX. An insulating layer 114 is deposited on the upper surfaces of the insulating layer 113 and a part of the protruding portion VX in the Z2 direction. Then, an insulating layer 115 is provided so as to cover the insulating layer 114. The thickness of the insulating layer 114 is negligible with regard to the insulating layers 113 and 115. The insulating layers 113 and 115 may contain silicon oxide as an insulating material. For the insulating layer 114, an insulating material having a metal antioxidant function is adopted. The insulating layer 114 may contain silicon carbonitride (SiCN) or silicon nitride (SiN).

An interconnect layer 116 is deposited on the upper surface of the insulating layer 115 in the Z2 direction. The interconnect layer 116 in the core region CR includes an interconnect portion MA and a connection portion VAB. The connection portion VAB is in contact with the protruding portion VX from which the insulating layers 114 and 115 have been removed. The interconnect portion MA is positioned on the side opposite the conductive layer 101 with respect to the connection portion VAB. That is, the interconnect portion MA is arranged on the Z2 direction side with respect to the connection portion VAB. The interconnect layer 116 is separated from the insulating layer 113. As a result, the interconnect layer 116 in the core region CR is electrically coupled to the source line SL. The interconnect layer 116 may contain aluminum (Al) and a barrier metal that covers the aluminum (Al).

An insulating layer 117 is provided on the upper surface of the interconnect layer 116 in the Z2 direction. An insulating layer 118 is provided on the upper surface of the insulating layer 117 in the Z2 direction. A surface protective layer 119 is provided on the upper surface of the insulating layer 118 in the Z2 direction. The insulating layer 117 may contain silicon oxide as an insulating material. The insulating layer 118 may contain silicon nitride as a low-permeability insulating material. The surface protective layer 119 may contain a resin material such as polyimide.

### (Peripheral Circuit Region PR)

The peripheral circuit region PR of the memory chip 100 will be described next.

In the peripheral circuit region PR, an interconnect structure for connecting the source line SL and the circuit chip 200 and an interconnect structure for connecting the external power supply and the circuit chip 200 are provided. The interconnect structure for connecting the source line SL and the circuit chip 200 and the interconnect structure for connecting the external power supply and the circuit chip 200 are electrically insulated from each other. These interconnect structures may include a contact CC. The contact CC includes a plurality of conductors 130. The interconnect structure for connecting the source line SL and the circuit chip 200 will be described below.

The interconnect layer 116 provided in the peripheral circuit region PR includes an interconnect portion MA and a connection portion VAC. The connection portion VAC is in contact with the conductors 130 in a region where the conductive layer 101 and insulating layers 113 to 115 are removed. The interconnect portion MA is provided on the Z2 direction side with respect to the connection portion VAC. An insulating layer 115 is provided between the connection portion VAC and the conductive layer 101, insulating layer 113, and insulating layer 114. The insulating layer 121 is provided in the conductive layer 101 in the peripheral circuit region PR and also in the outer regions of the peripheral circuit region PR. The insulating layer 121 may contain silicon nitride.

The conductor 130 is shaped into a circular cylinder extending in the Z direction. The Z2 direction-side end portions of the conductors 130 are positioned closer to the structure on the Z1 direction side of the conductive layer 101 than the Z2 direction-side upper surface of the portion of the conductive layer 101 that does not include the protruding portion VX. The Z2 direction-side end portions of the conductors 130 are positioned within the connection portion VAC of the interconnect layer 116. The Z1 direction-side end portions of the conductors 130 are electrically coupled to the electrode 211 of the circuit chip 200 by way of the conductors 105, interconnect layer 106, conductor 107, interconnect layer 108, conductor 109, and electrode 110. The conductors 105, 107, and 109 arranged in the peripheral circuit region PR are each shaped into a circular cylinder extending in the Z direction.

### (Wall Region)

The wall region WR of the memory chip 100 will be described.

In the wall region WR, a wall structure W and various interconnects connecting the wall structure W to the circuit chip 200 are provided. The wall structure W includes a part of the interconnect layer 116, and wall structures W1, W2, and W3. The wall structures W1 to W3 include conductors 120_1 to 120_3, respectively. The interconnect layer 116 provided in the wall region WR is electrically insulated from the interconnect layer 116 provided in the core region CR and peripheral circuit region PR.

The interconnect layer 116 in the wall region WR includes a connection portion VAD. The connection portion VAD is in contact with the conductors 120_1 to 120_3 in a region where the conductive layer 101 and insulating layers 113 to 115 are removed. An insulating layer 115 is provided between the connection portion VAD and the conductive layer 101, insulating layer 113, and insulating layer 114.

The conductor 120_1 is shaped into a rectangular ring surrounding the core region CR and peripheral circuit region PR when viewed in the Z direction. The conductor 120_2 is shaped into a rectangular ring surrounding the conductor 120_1 when viewed in the Z direction. The conductor 120_3 is shaped into a rectangular ring surrounding the conductor 120_2 when viewed in the Z direction.

The conductors 120_1 to 120_3 each extend in the Z direction. The Z2 direction-side end portions of the conductors 120_1 to 120_3 are positioned closer to the structure on the Z1 direction side of the conductive layer 101 than the Z2 direction-side upper surface of the portion of the conductive layer 101 that does not include the protruding portion VX. The Z2 direction-side end portions of the conductors 120_1 to 120_3 may be positioned within the connection portion VAD of the interconnect layer 116.

The Z1 direction-side end portion of the conductor 120_1 is not connected to the conductor 105. The Z1 direction-side end portion of the conductor 120_2 and the Z1 direction-side end portion of the conductor 120_3 are electrically coupled to the respective electrodes 211 of the circuit chip 200 by way of the respective conductors 105, interconnect layers 106, conductors 107, interconnect layers 108, conductors 109, and electrodes 110.

The conductor 105, interconnect layer 106, conductor 107, interconnect layer 108, conductor 109, and electrode 110 that are electrically coupled to the conductor 120_2 may be shaped into a rectangular ring surrounding the core region CR and peripheral circuit region PR when viewed in the Z direction. The conductor 105, interconnect layer 106, conductor 107, interconnect layer 108, conductor 109, and electrode 110 electrically coupled to the conductor 120_3 may be shaped into a rectangular ring surrounding the conductor 105, interconnect layer 106, conductor 107, interconnect layer 108, conductor 109, and electrode 110, which are electrically coupled to the conductor 120_2, when viewed in the Z direction.

In the interconnect layer 108 electrically coupled to the conductor 120_2, its portion connected to the conductor 109 is positioned closer to the peripheral circuit region PR than the portion connected to the conductor 107. That is, the conductor 107 and conductor 109 that are respectively connected to the upper and lower surfaces of the interconnect layer 108 electrically coupled to the conductor 120_2 are not aligned with each other in the Z direction. In the interconnect layer 108 electrically coupled to the conductor 120_3, its portion connected to the conductor 109 is positioned closer to the circumferential region OR than the portion connected to the conductor 107. That is, the conductor 107 and conductor 109 that are respectively connected to the upper and lower surfaces of the interconnect layer 108 electrically coupled to the conductor 120_3 are not aligned with each other in the Z direction.

### (Circumferential Region)

The circumferential region OR of the memory chip 100 will be described.

The conductive layer 101 provided in the circumferential region OR is electrically insulated from the conductive layer 101 provided in the core region CR, peripheral circuit region PR, and wall region WR. When the conductive layer 101 provided in the circumferential region OR is specified, it will be denoted as “conductive layer 101_1”. At least a part of the conductive layer 101_1 is left uncovered (unprotected) by the surface protective layer 119. That is, at least a part of the conductive layer 101_1 is not arranged between the circuit chip 200 and surface protective layer 119 in the Z direction.

The conductive layer 101_1 has on its upper surface in the Z2 direction a plurality of protruding portions ACP that extend in the Z2 direction. These protruding portions ACP may penetrate the insulating layer 113. The upper surfaces of the protruding portions ACP in the Z2 direction are in contact with the insulating layer 114. That is, the protruding portions ACP have a thickness approximately the same as that of the protruding portion VX. The insulating layer 121 inside the conductive layer 101_1 is partitioned at a portion overlapping the protruding portions ACP when viewed in the Z direction, by the conductive layer 101_1. The protruding portions ACP are used in the process of manufacturing the memory chip 100 for grounding of the conductive layer 101 to the substrate of the memory chip 100 (not shown), thereby suppressing arcing that tends to be caused by charging-up in the conductive layer 101 at the time of dry etching. The protruding portions ACP may not always need to be provided.

### 1.1.6.2 Cross-Sectional Structure of Circuit Chip

Next, the cross-sectional structure of the circuit chip 200 will be explained.

In the core region CR and peripheral circuit region PR, a plurality of transistors TR are provided on the upper surface of the semiconductor substrate 201 in the Z2 direction. Each transistor TR is used as an element in the command register 11, address register 12, sequencer 13, driver module 14, row decoder module 15, and sense amplifier module 16. The transistor TR includes a source and a drain, which are not shown, formed in the semiconductor substrate 201, a gate insulating film 202, and a gate electrode 203. The gate insulating film 202 is provided on the upper surface of the semiconductor substrate 201 in the Z2 direction. The gate electrode 203 is provided on the upper surface of the gate insulating film 202 in the Z2 direction.

In the core region CR and peripheral circuit region PR, a conductor 204 is provided on the upper surfaces of the gate electrode 203, source, and drain in the Z2 direction. In the wall region WR, a conductor 204 is provided on the upper surface of the N-type impurity diffusion region NW of the semiconductor substrate 201 and on the upper surface of the P-type impurity diffusion region PW of the semiconductor substrate 201 in the Z2 direction.

An interconnect layer 205 is arranged on the upper surface of the conductor 204 in the Z2 direction. A conductor 206 is arranged on the upper surface of the interconnect layer 205 in the Z2 direction. An interconnect layer 207 is arranged on the upper surface of the conductor 206 in the Z2 direction. A conductor 208 is arranged on the upper surface of the interconnect layer 207 in the Z2 direction. An interconnect layer 209 is arranged on the upper surface of the conductor 208 in the Z2 direction. A conductor 210 is arranged on the upper surface of the interconnect layer 209 in the Z2 direction. The conductors 204, 206, 208, and 210 in the core region CR and peripheral circuit region PR may be each shaped into a circular cylinder extending in the Z direction. The conductors 204, 206, 208, and 210, the interconnect layers 205, 207, and 209, and the electrodes 211 in the wall region WR may be shaped into a rectangular ring surrounding the core region CR and peripheral circuit region PR when viewed in the Z direction. In a similar manner, the N-type impurity diffusion region NW and P-type impurity diffusion region PW in the wall region WR may also be shaped into a rectangular ring.

An insulating layer 212 is provided on the upper surface of the semiconductor substrate 201 in the Z2 direction. This insulating layer 212 is arranged so as to cover the transistors TR, conductors 204, interconnect layers 205, conductors 206, interconnect layers 207, conductors 208, interconnect layers 209, and conductors 210. An insulating layer 213 is provided on the upper surface of the insulating layer 212 in the Z2 direction.

Electrodes 211 are provided on the upper surface of the conductor 210 in the Z2 direction at the same level as the insulating layer 213. The electrodes 211 are connected to the corresponding electrodes 110 and are thereby electrically coupled to the interconnects in the memory chip 100.

The gate electrodes 203, conductors 204, 206, 208, and 210, and interconnect layers 205, 207, and 209 may be formed of a conductive material, including a metallic material, a p-type semiconductor, or an n-type semiconductor. The electrode 211 may contain copper. The gate insulating film 202, insulating layer 212, and insulating layer 213 may contain silicon oxide as an insulating material.

### 1.1.7 Connection Between Core Region and Peripheral Circuit Region

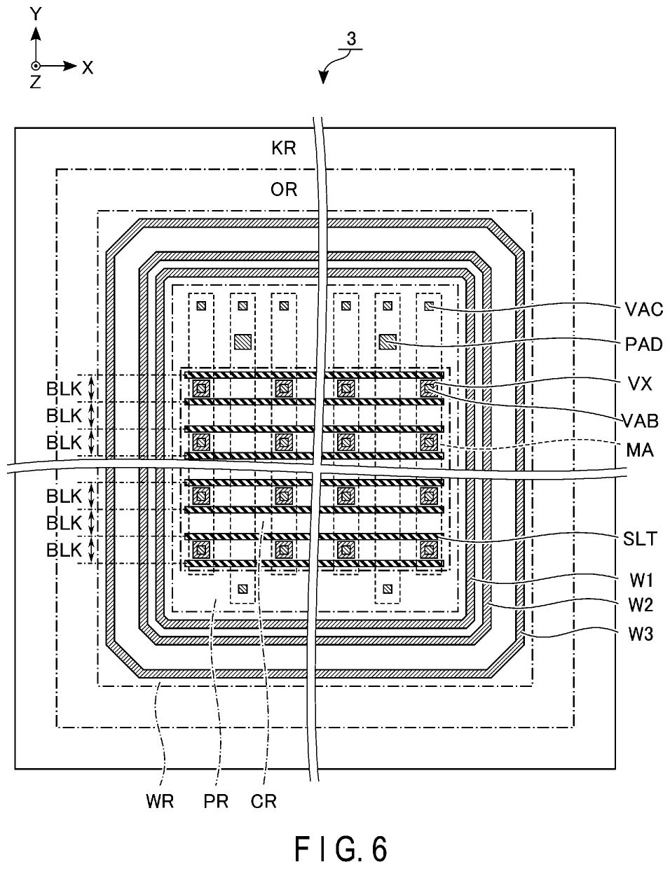

FIG. 6 is a plan view showing an exemplary planar layout of wall structures and connection wirings between the core region and peripheral circuit region in the memory device according to the first embodiment. The members SLT, protruding portions VX, connection portions VAB and VAC, external connection pad portions PAD, and wall structures W1 to W3 are hatched in FIG. 6. The interconnect portions MA each connecting a plurality of connection portions VAB and one connection portion VAC and the interconnect portions MA each connecting two connection portions VAC are indicated with dashed lines in FIG. 6.

An area between any two adjacent members SLT in the core region CR serves as a block region for a block BLK. The protruding portions VX are aligned in the X direction in the same block region. The protruding portions VX in different block regions are aligned in the Y direction. In the example of FIG. 6, block regions with protruding portions VX and block regions with no protruding portion VX are alternately arranged.

The interconnect portions MA each extend in the Y direction and are aligned in the X direction. In the example of FIG. 6, interconnect portions MA each connecting the connection portions VAB and VAC and interconnect portions MA each connecting two connection portions VAC are alternately arranged in the X direction. An interconnect portion MA mutually connecting the connection portions VAB and VAC corresponds to the interconnect layer 116 included in the interconnect structure that connects the source line SL and circuit chip 200. A connection portion VAB is arranged at a position where it overlaps its corresponding protruding portion VX when viewed in the Z direction. The region of the connection portion VAB viewed in the Z direction is arranged within the region of this protruding portion VX.

An interconnect portion MA mutually connecting two connection portions VAC corresponds to the interconnect layer 116 included in the interconnect structure for connecting the external power supply and the circuit chip 200. In the interconnect structure connecting the external power supply and the circuit chip 200, an external connection pad portion PAD, in which the upper surfaces of the interconnect portions MA are partially exposed without being covered by the surface protective layer 119 or the like, is formed in a region where a connection portion VAC is not provided.

### 1.1.8 Planar Layout of Block Region

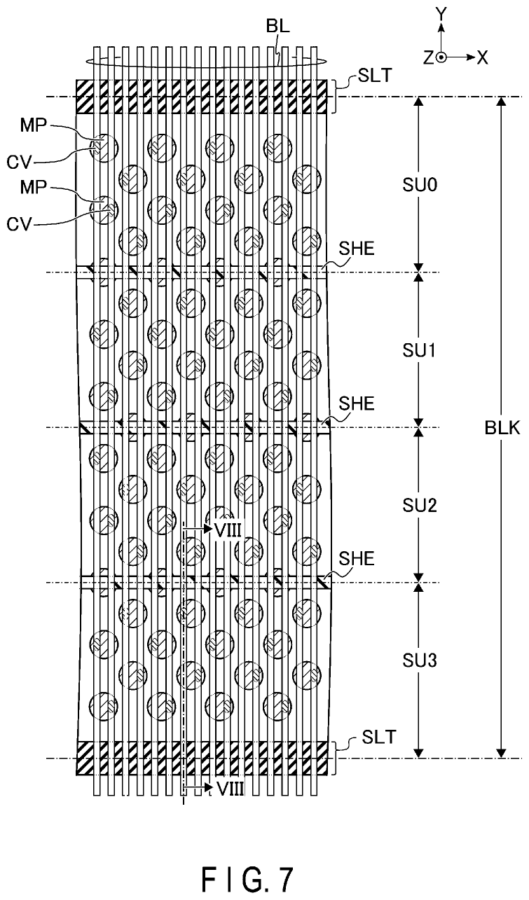

FIG. 7 is a plan view showing an exemplary planar layout of a block region in the memory device according to the first embodiment. A block region and two members SLT sandwiching this block region are illustrated in FIG. 7. In the block region shown in FIG. 7, the memory cell array 10 includes three members SHE, a plurality of memory pillars MP, a plurality of contacts CV, and a plurality of bit lines BL.

Each of the memory pillars MP may serve as a NAND string NS. These multiple memory pillars MP are arranged, for example, in a staggered manner in nineteen rows in a region between two adjacent members SLT. The memory pillars MP in, for example, the fifth row from the top of the drawing sheet overlap with a member SHE, and similarly, the memory pillars in each of the tenth row and the fifteenth row overlap with a corresponding member SHE.

A member SHE may be a plate-shaped insulating member that extends along the XZ plane. Three members SHE are aligned in the Y direction between the adjacent members SLT. Each of the members SHE partitions the interconnect layer 103 corresponding to the select gate line SGD in the Y direction. A portion between two adjacent members SHE or a portion between a member SLT and a member SHE corresponds to one string unit SU.

The bit lines BL each extend in the Y direction and are aligned in the X direction. Each bit line BL overlaps at least one memory pillar MP for every string unit SU. In the example shown in FIG. 7, two bit lines BL overlap one memory pillar MP. In the structure where multiple bit lines BL overlap one memory pillar MP, one of such bit lines BL and the corresponding memory pillar MP are electrically connected to each other by way of a contact CV.

The contact CV between the bit lines BL and a memory pillar MP that is in contact with the member SHE may be omitted. In other words, a contact CV for a memory pillar MP and the bit lines BL may be omitted if the memory pillar MP is in contact with two different select gate lines SGD. The numbers or the layout of the memory pillars MP and members SHE arranged between any two adjacent members SLT are not limited to the structure described with reference to FIG. 7, but may be modified as appropriate. The number of bit lines BL overlapping a memory pillar MP can be freely designed.

### 1.1.9 Cross-Sectional Structure of Block Region

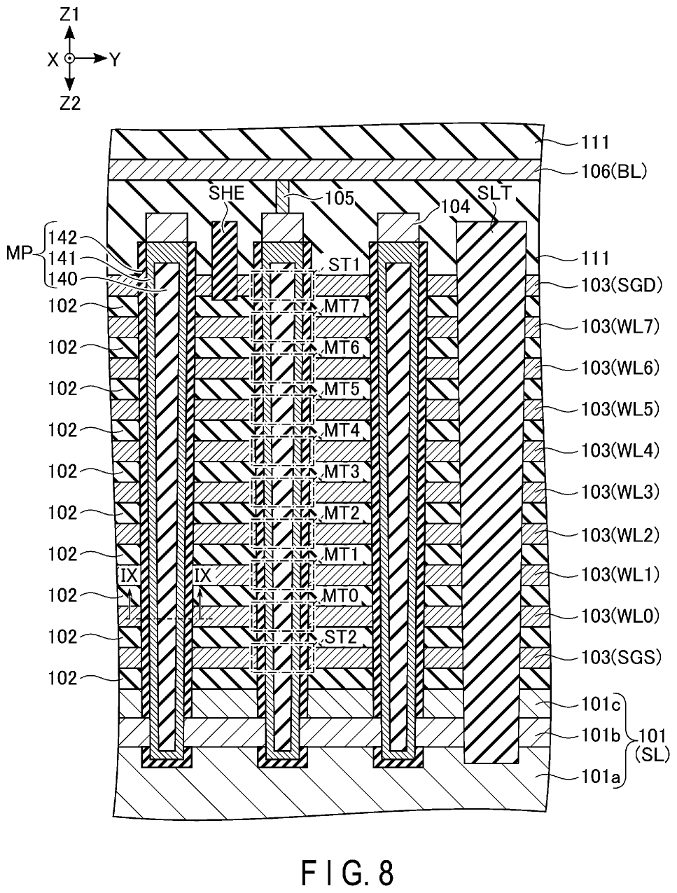

FIG. 8 is a cross-sectional view taken along line VIII-VIII of FIG. 7, showing an exemplary cross-sectional structure of a block region in the memory device according to the first embodiment.

As illustrated in FIG. 8, the conductive layer 101 may include three conductive layers 101a, 101b, and 101c. The conductive layer 101b is deposited on the upper surface of the conductive layer 101a in the Z1 direction. The conductive layer 101c is deposited on the upper surface of the conductive layer 101b in the Z1 direction. The conductive layer 101b may be formed by replacing the insulating layer 121 provided between the conductive layer 101a and conductive layer 101c. The conductive layers 101a to 101c may contain silicon as a semiconductor. The conductive layers 101a to 101c may also contain phosphorus (P) as impurities for the semiconductor.

Ten insulating layers 102 and ten interconnect layers 103 are alternately stacked on the upper surface of the conductive layer 101 in the Z1 direction. In the example of FIG. 8, the ten interconnect layers 103 respectively serve as a select gate line SGS, word lines WL0 to WL7, and a select gate line SGD, in order from the conductive layer 101 side. For each of the interconnect layers 103 that serve as the select gate lines SGS and SGD, more than one layer may be provided. As a conductive material for the interconnect layers 103, a layer stack of titanium nitride (TiN) and tungsten (W) may be adopted. In such a structure, titanium nitride is formed to cover tungsten. The titanium nitride serves, during chemical vapor deposition (CVD) for formation of a tungsten layer, as a barrier layer suppressing oxidation of the tungsten or as an adhesion layer improving adhesion of the tungsten. The interconnect layer 103 may contain a high dielectric constant material such as aluminum oxide (AlO). In such a structure, the high dielectric constant material is provided so as to cover the conductive material. For instance, in each of the interconnect layers 103, the high dielectric constant material may be provided in such a manner as to be in contact with the insulating layers 102 deposited above and below the interconnect layers 103 and also with the side surface of the memory pillar MP. The titanium nitride is deposited so as to be in contact with this high-permittivity material. The tungsten is provided in such a manner as to be in contact with the titanium nitride and embedded inside the interconnect layers 103. An insulating layer 111 is deposited on the upper surface of the interconnect layer 103 in the Z1 direction that serves as a select gate line SGD.

The member SLT partitions the multiple insulating layers 102 and the multiple interconnect layers 103 in the Y direction. The end portion (bottom surface) of the member SLT in the Z2 direction reaches the conductive layer 101a.The member SHE partitions the interconnect layer 103 that serves as the select gate line SGD in the Y direction. The end portion (bottom surface) of the member SHE in the Z2 direction reaches the insulating layer 102 deposited between the interconnect layer 103 serving as the select gate line SGD and the interconnect layer 103 serving as the word line WL7.

The memory pillar MP is shaped into approximately a circular cylinder extending in the Z direction. The memory pillar MP penetrates the ten interconnect layers 103. The bottom surface of the memory pillar MP reaches the conductive layer 101a. The memory pillar MP may have a structure in which multiple pillars are coupled in the Z direction.

Next, the interior structure of the memory pillar MP will be described. The memory pillar MP includes a core film 140, a semiconductor film 141, and a lamination film 142. The core film 140 extends in the Z direction. The end portion of the core film 140 in the Z1 direction may reach the insulating layer 111, and the end portion of the core film 140 in the Z2 direction may reach the conductive layer 101a. The semiconductor film 141 surrounds the core film 140. At the end portion of the memory pillar MP in the Z2 direction, a part of the semiconductor film 141 is in contact with the conductive layer 101b. At the end portion of the memory pillar MP in the Z1 direction, a part of the semiconductor film 141 is in contact with the conductor 104. The lamination film 142 covers the side surface and Z2 direction-side end portion of the semiconductor film 141, except for the portion where the semiconductor film 141 is in contact with the conductive layer 101b. The core film 140 may contain an insulator such as silicon oxide. The semiconductor film 141 may contain silicon.

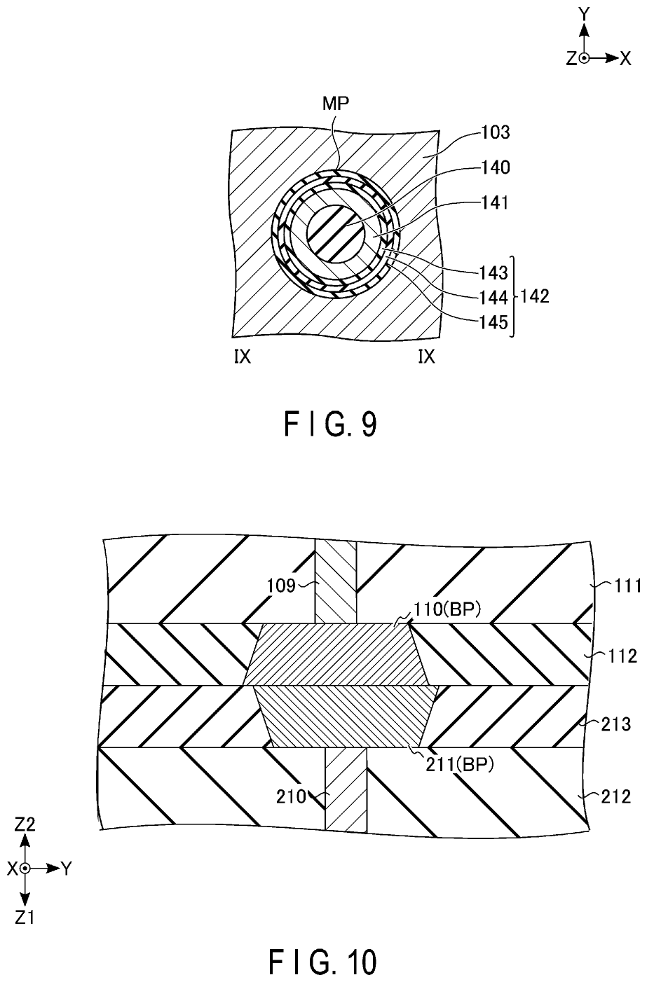

FIG. 9 is a cross-sectional view taken along line IX-IX of FIG. 8, showing an exemplary cross-sectional structure of a memory pillar in the memory device according to the first embodiment. In particular, FIG. 9 shows a cross-sectional structure of the memory pillar MP taken along a line parallel to the XY plane at a level of a layer that includes an interconnect layer 103. The lamination film 142 may include a tunnel insulating film 143, a charge storage film 144, and a block insulating film 145, as illustrated in FIG. 9.

In the cross section that includes the interconnect layer 103, the core film 140 may be provided at the central portion of the memory pillar MP. The semiconductor film 141 surrounds the side surface of the core film 140. The tunnel insulating film 143 surrounds the side surface of the semiconductor film 141. The charge storage film 144 surrounds the side surface of the tunnel insulating film 143. The block insulating film 145 surrounds the side surface of the charge storage film 144. The interconnect layer 103 surrounds the side surface of the block insulating film 145. The tunnel insulating film 143 and block insulating film 145 each contain silicon oxide. The charge storage film 144 has a function of storing electric charges, and may contain silicon nitride.

A memory pillar MP combined with the interconnect layers 103 that function as word lines WL0 to WL7 constitutes memory cell transistors MT0 to MT7. Similarly, the memory pillar MP combined with the interconnect layer 103 that functions as a select gate line SGD constitutes a select transistor ST1. The memory pillar MP combined with the interconnect layer 103 that functions as a select gate line SGS constitutes a select transistor ST2. Each memory pillar MP thereby functions as a NAND string NS.

### 1.1.10 Cross-Sectional Structure of Bonding Pad

Next, the cross-sectional structure of the bonding pad BP will be described.

FIG. 10 is a cross-sectional view showing an exemplary cross-sectional structure of bonding pads in the memory device according to the first embodiment. In the example of FIG. 10, electrodes 110 and 211 are illustrated.

At the step of adhering the memory chip 100 and circuit chip 200, the electrode 110 is connected to the electrode 211, as illustrated in FIG. 10. In the example of FIG. 10, the area of the electrode 110 at the bonded surface is approximately equal to the area of the electrode 211. Under such circumstances, if copper is used for the electrode 110 and electrode 211, the copper of the electrode 110 may become integrated with the copper of the electrode 211, and their boundary may become difficult to recognize. If there is a displacement in adhering the electrode 110 and electrode 211, however, the adhesion can be recognized from distortion of the bonded structure or from displacement of the barrier metal for the copper (discontinuous area in the side surface).

If the electrodes 110 and 211 are formed through a damascene process, their side surfaces will have tapered shapes. In the cross section of the bonded portion of the electrode 110 and electrode 211 along the Z direction, the side walls will not extend in a straight line and will become non-rectangular.

When the electrode 110 and electrode 211 are bonded to each other, a barrier metal is adopted to cover the bottom, side, and top surfaces of the copper for these electrodes. The ordinary interconnect layers formed of copper, on the other hand, have an insulating layer (e.g., silicon nitride or silicon carbonitride) formed on the upper surface of the copper so as to bring about an antioxidant function for the copper, and no barrier metal is provided. This means that, even without a displacement in the adhesion, the bonded structure is still distinguishable from ordinary interconnect layers.

### 1.2 Manufacturing Method

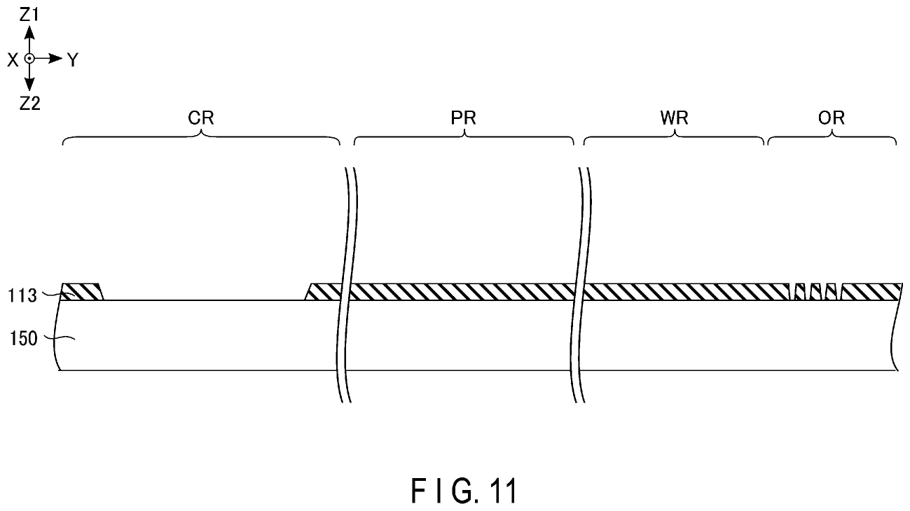

FIGS. 11 to 19 are cross-sectional views each showing an exemplary cross-sectional structure of the memory device according to the first embodiment in the course of manufacturing.

First, an insulating layer 113 is formed on the upper surface of the semiconductor substrate 150 in the Z1 direction, as illustrated in FIG. 11. Thereafter, the insulating layer 113 is processed so as to form grooves corresponding to the protruding portions ACP in the circumferential region OR and a hole corresponding to the protruding portion VX in the core region CR. The diameter of the hole corresponding to the protruding portion VX is larger than the width of a groove corresponding to a protruding portion ACP.

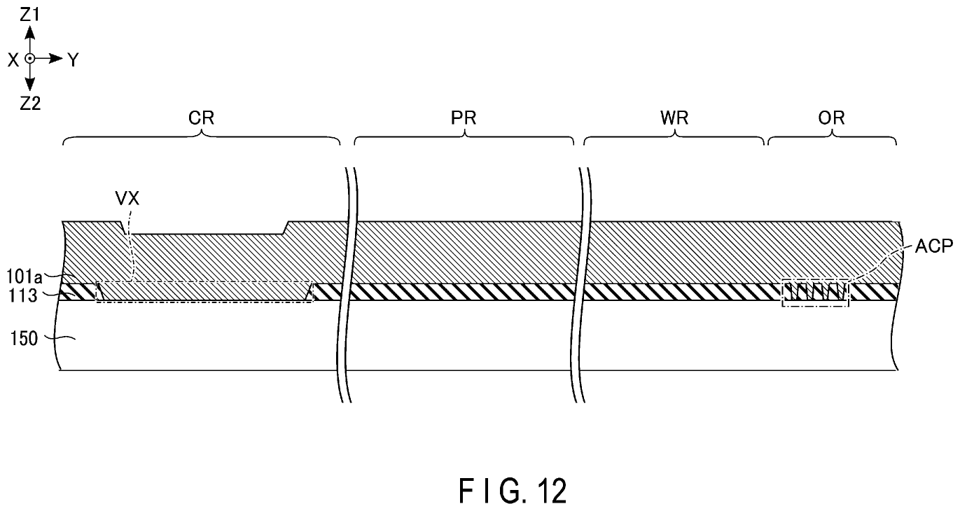

Next, a conductive layer 101a is formed, for example through CVD, as illustrated in FIG. 12. During this process, the hole corresponding to the protruding portion VX and the grooves corresponding to the protruding portions ACP are filled in, as a result of which protruding portions VX and ACP are formed. The protruding portions VX and ACP are in contact with the semiconductor substrate 150. The hole corresponding to the protruding portion VX has a significantly large diameter with reference to the thickness of the conductive layer 101a. For this reason, the flatness of the upper surface of the conductive layer 101a in the Z1 direction may be impaired in the region where a protruding portion VX is provided.

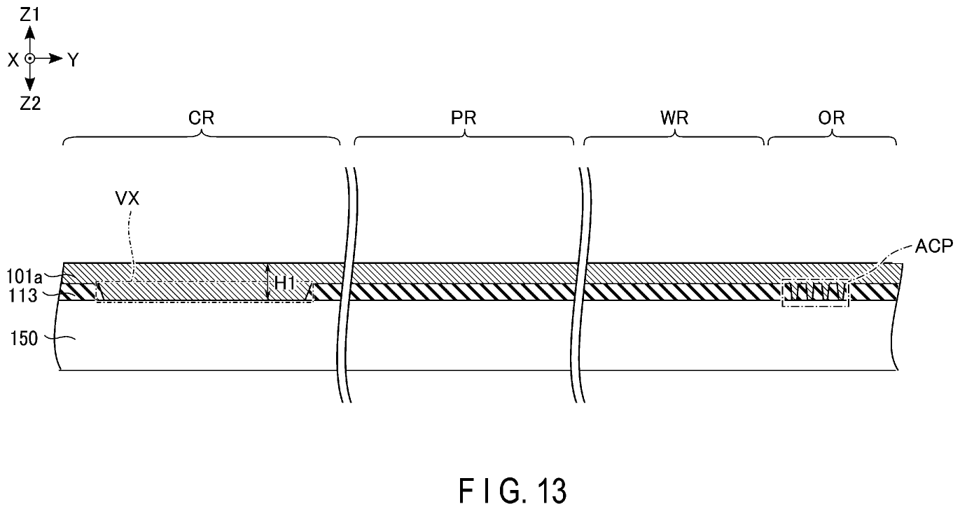

The conductive layer 101a is therefore processed to planarize its Z1 direction-side upper surface, as illustrated in FIG. 13. For instance, after polishing the conductive layer 101a through chemical mechanical polishing (CMP) until the insulating layer 113 is exposed, the conductive layer 101a may be additionally formed. Alternatively, the conductive layer 101a may be polished through blind CMP to a degree that the insulating layer 113 will not be exposed. In either case, the portion of the conductive layer 101a having the protruding portion VX is controlled to have a predetermined thickness H1. The thickness H1 is preferably around 400 nanometers.

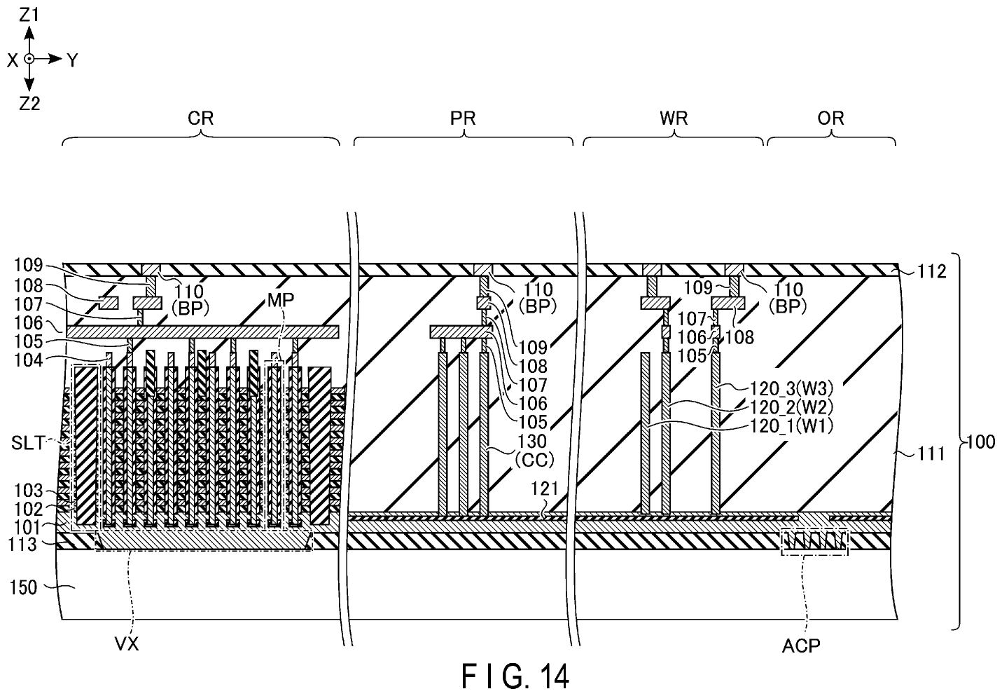

Thereafter, as illustrated in FIG. 14, the remaining portion of the memory chip 100 is formed on the upper surface of the conductive layer 101a in the Z1 direction. The circuit chip 200 is formed in parallel to the formation of the memory chip 100, although it is not shown in this drawing.

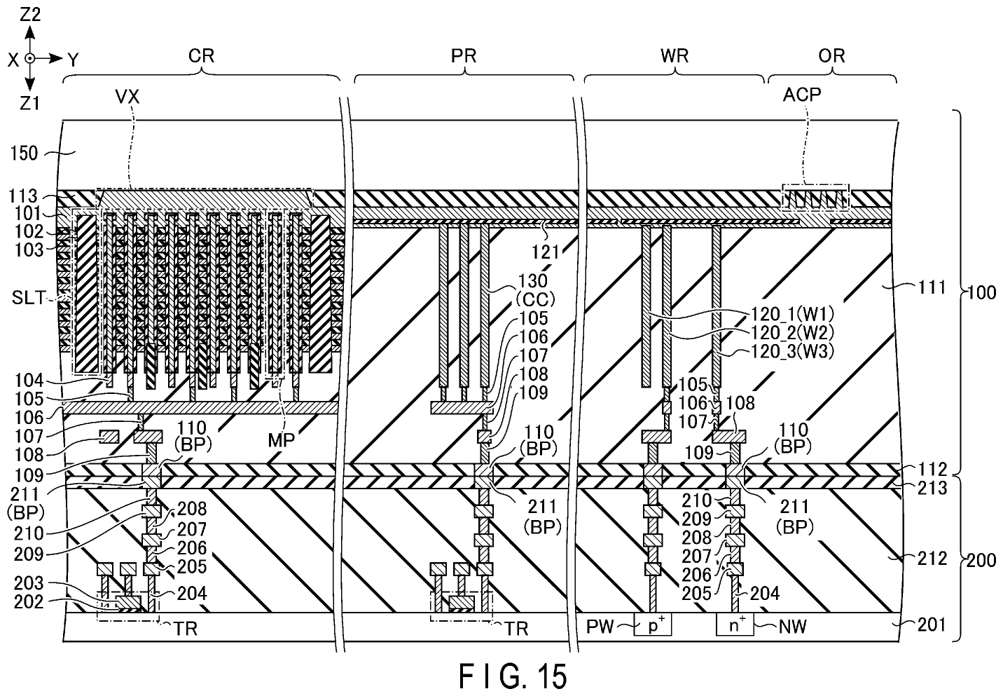

Next, the memory chip 100 and circuit chip 200 are bonded to each other such that the electrodes 110 and electrodes 211 are in contact with each other, as illustrated in FIG. 15.

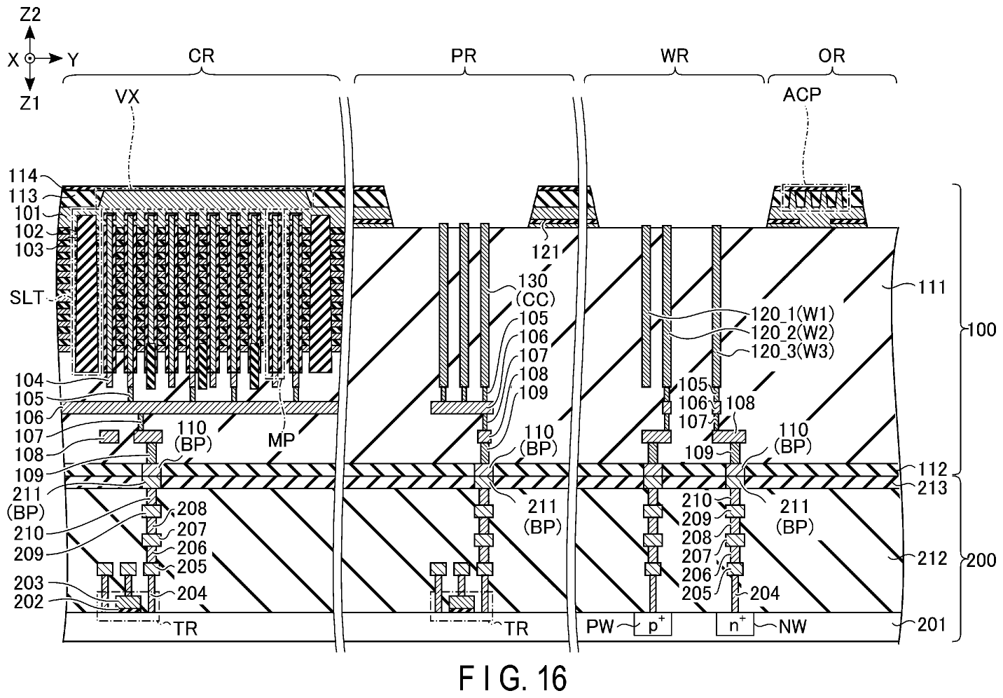

After the semiconductor substrate 150 is removed from the memory chip 100, the insulating layer 114 is formed in such a manner as to cover the insulating layer 113 and protruding portions VX and ACP, as illustrated in FIG. 16. The insulating layers 113 and 114 are processed, and then the conductive layer 101 including the insulating layer 121 is processed so that a hole in the peripheral circuit region PR and a groove in the wall region WR are formed together. In the circumferential region OR and kerf region KR, the peripheral portion outside the protruding portions ACP is removed. The hole formed in the peripheral circuit region PR corresponds to the region in which the connection portion VAC is to be formed. The groove formed in the wall region WR corresponds to the region in which the connection portion VAD is to be formed. In this manner, the conductors 130 are exposed in the hole formed in the peripheral circuit region PR, and the conductors 120_1 to 120_3 are exposed in the groove formed in the wall region WR.

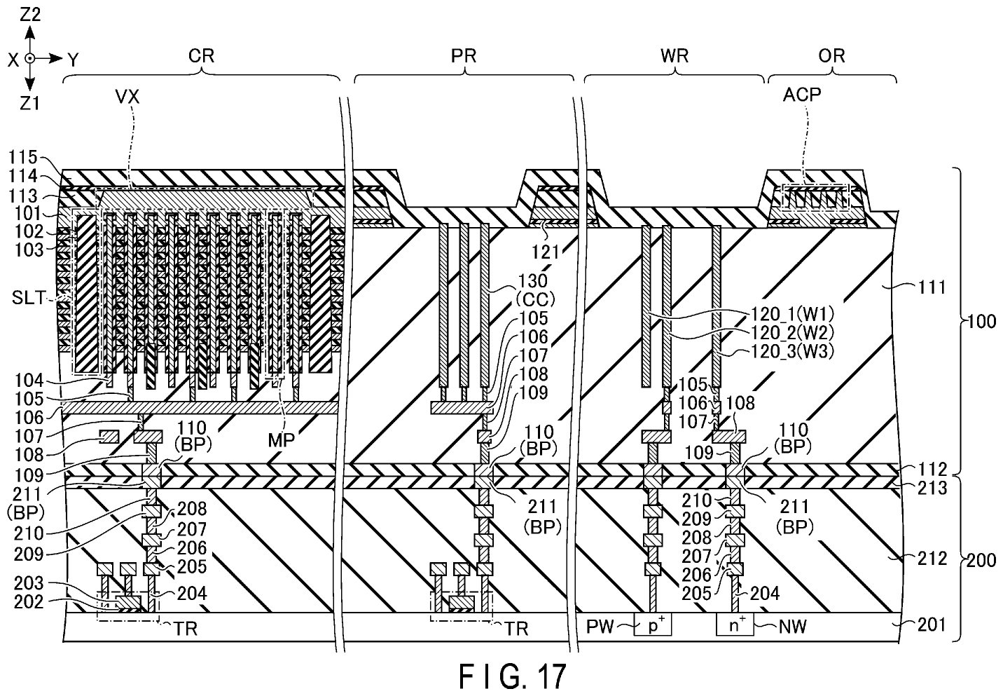

Next, as illustrated in FIG. 17, the insulating layer 115 is formed on the upper surface of the structure in the Z2 direction.

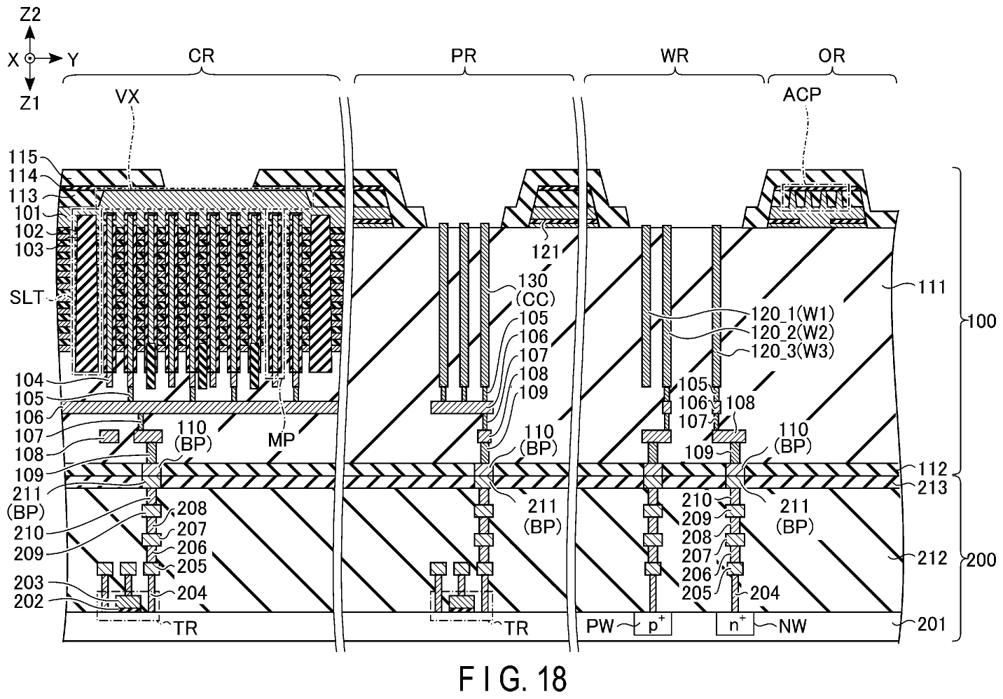

Then, as illustrated in FIG. 18, the insulating layers 114 and 115 are processed so that holes in the core region CR and in the peripheral circuit region PR and a groove in the wall region WR are formed at the same time. The hole formed in the core region CR corresponds to the region in which the connection portion VAB is to be formed. The hole formed in the peripheral circuit region PR corresponds to the region in which the connection portion VAC is to be formed. The groove formed in the wall region WR corresponds to the region in which the connection portion VAD is to be formed. In this manner, the protruding portion VX is exposed in the hole formed in the core region CR, the conductors 130 are exposed in the hole formed in the peripheral circuit region PR, and the conductors 120_1 to 120_3 are exposed in the grooves formed in the wall regions WR.

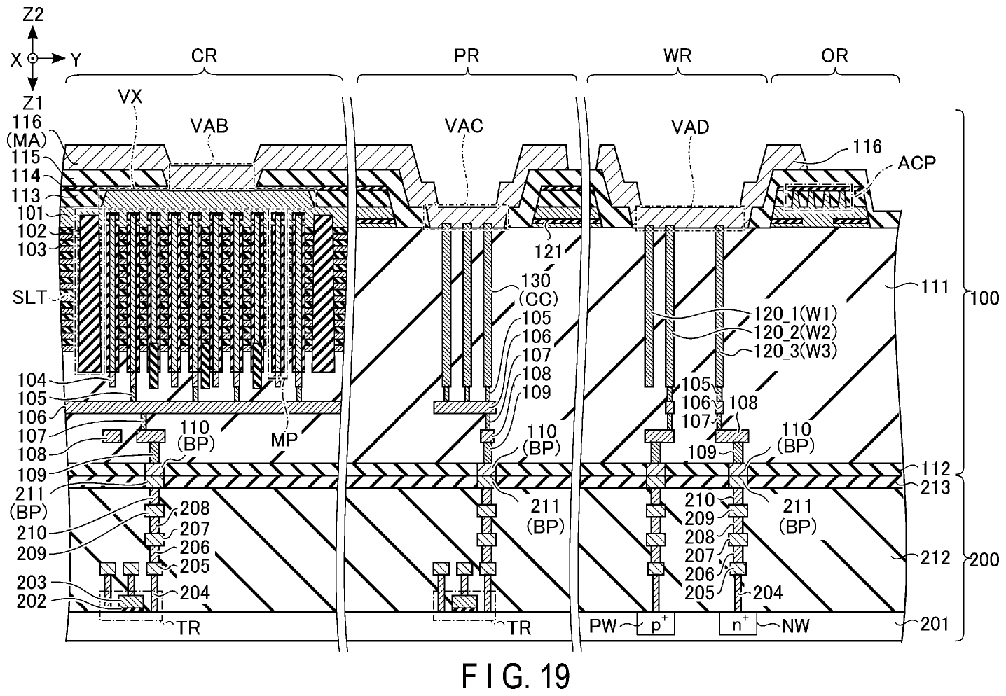

Next, the interconnect layer 116 is formed on the upper surface of the structure in the Z2 direction, as illustrated in FIG. 19. The holes formed in the core region CR and peripheral circuit region PR and the groove formed in the wall region WR are filled in with an interconnect layer 116. As a result, the connection portions VAB, VAC, and VAD are formed. Thereafter, the interconnect layer 116 is processed so as to be separated into the interconnect layer 116 in the core region CR and peripheral circuit region PR and the interconnect layer 116 in the wall region WR. The interconnect layer 116 in the core region CR and peripheral circuit region PR is separated into several portions. Furthermore, a part of the interconnect layer 116 is removed from the kerf region KR and circumferential region OR.

Thereafter, the structure on the Z2 direction side of the interconnect layer 116 is formed. The memory device 3 is thereby completed.

### 1.3 Effects of First Embodiment

According to the first embodiment, yield can be improved in manufacturing the memory device 3. This effect will be explained below.

The conductive layer 101 includes on its interconnect layer 116-side surface a protruding portion VX that protrudes with respect to the surrounding region. The protruding portion VX has a thickness approximately the same as that of the insulating layer 113. This makes it unnecessary to process the insulating layer 113 at the time of forming a hole corresponding to the connection portion VAB in the interconnect layer 116. In other words, the amount of processing for formation of the hole corresponding to the connection portion VAB can be reduced to the same extent as the amount of processing for formation of the hole corresponding to the connection portion VAC and the groove corresponding to the connection portion VAD. As a result, when forming the hole corresponding to the connection portion VAB, the hole corresponding to the connection portion VAC, and the groove corresponding to the connection portion VAD all together, excessive exposure of the conductor 130 can be suppressed.

The portion of the conductive layer 101a having the protruding portion VX is formed to be as thick as 400 nanometers. For this reason, during the processing of a hole corresponding to the connection portion VAB, unevenness in the portion between the exposed end portions of the memory pillars MP and the exposed surface of the conductive layer 101 can be reduced. Thus, insufficient formation of a barrier metal due to the uneven portion can be prevented, and therefore diffusion of aluminum (Al) into the memory pillar MP can be prevented at the time of forming the interconnect layer 116.

The portion of the conductive layer 101a that does not include the protruding portion VX is significantly thinner than 400 nanometers. Thus, the amount of processing for removal of the conductive layer 101 from the regions where a hole corresponding to the connection portion VAC is formed and where a groove corresponding to the connection portion VAD is formed can be reduced in comparison with processing of a semiconductor layer having a uniform thickness of approximately 400 nanometers. As a result, the processing time to remove the conductive layer 101 from the regions where a hole corresponding to the connection portion VAC and a groove corresponding to the connection portion VAD are formed can be reduced.

The protruding portion VX is formed together with the protruding portions ACP. This can enhance yield in producing the memory device 3, without adding an extra processing step.

### 1.4 Modification of First Embodiment

In the first embodiment, the conductive layer 101 has been described as a continuous film including a protruding portion VX, which is not a limitation. The protruding portion VX may be formed to have film properties different from those of the remaining portion of the conductive layer 101, or formed from a material different from that of the remaining portion. The following description will basically focus on aspects of the structure and manufacturing method that differ from the first embodiment. Portions of the structure and manufacturing method similar to those of the first embodiment may be omitted from the description.

### 1.4.1 Cross-Sectional Structure of Memory Device

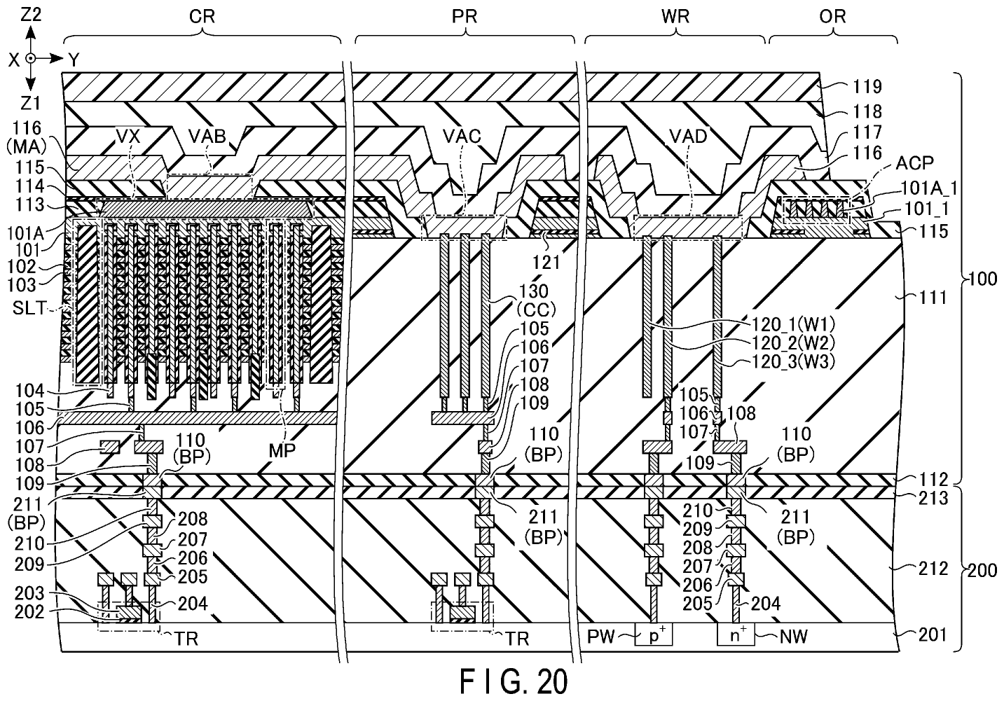

FIG. 20 is a cross-sectional view showing an exemplary cross-sectional structure of a memory device according to a modification of the first embodiment. FIG. 20 corresponds to the structure of FIG. 5 in the first embodiment.

As shown in FIG. 20, the conductive layer 101 does not include a protruding portion VX. A conductive layer 101A of approximately the same thickness as that of the insulating layer 113 is deposited on the upper surface of the conductive layer 101 in the Z2 direction so as to function as the protruding portion VX.

The conductive layer 101A may be formed of a different material from that of the conductive layer 101, such as a metal. If the material of the conductive layer 101A differs from that of the conductive layer 101, the conductive layer 101A may contain copper or tungsten. The conductive layer 101A may have film properties that differ from those of the conductive layer 101. If the conductive layer 101A differs from the conductive layer 101 in film properties, the conductive layer 101A may contain silicon. The crystalline size, for example, of the silicon in the conductive layer 101A differs from that of the silicon in the conductive layer 101.

Thus, when the conductive layer 101 and conductive layer 101A differ from each other in materials or film properties, the boundary between the conductive layer 101 and conductive layer 101A can be visually recognized. In other words, the conductive layers 101 and 101A will be discontinuous films.

Similarly, the conductive layer 101_1 does not include protruding portions ACP. A conductive layer 101A_1 of approximately the same thickness as that of the insulating layer 113 is deposited on the upper surface of the conductive layer 101_1 in the Z2 direction so as to function as the protruding portions ACP.

The conductive layer 101A_1 may be formed of a different material from that of conductive layer 101_1, such as a metal. If the material of the conductive layer 101A_1 differs from that of the conductive layer 101_1, the conductive layer 101A_1 may contain copper or tungsten. The conductive layer 101A_1 may have film properties that differ from those of the conductive layer 101_1. If the conductive layer 101A_1 differs from the conductive layer 101_1 in film properties, the conductive layer 101A_1 may contain silicon. The crystalline size, for example, of the silicon contained in the conductive layer 101A_1 differs from that of the silicon contained in the conductive layer 101_1.

Thus, when the conductive layer 101_1 and conductive layer 101A_1 differ from each other in materials or film properties, the boundary between the conductive layer 101_1 and conductive layer 101A_1 can be visually recognized. In other words, the conductive layers 101_1 and 101A_1 become discontinuous films.

### 1.4.2 Manufacturing Method

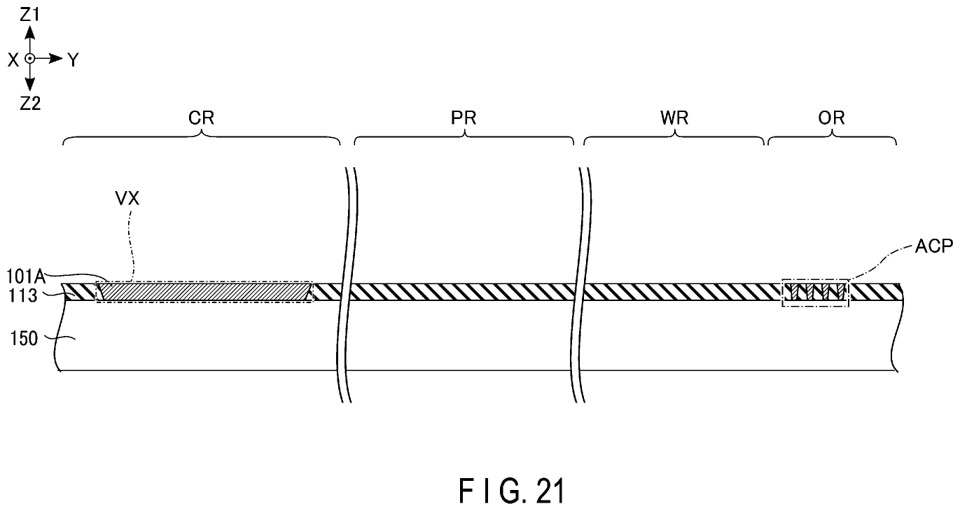

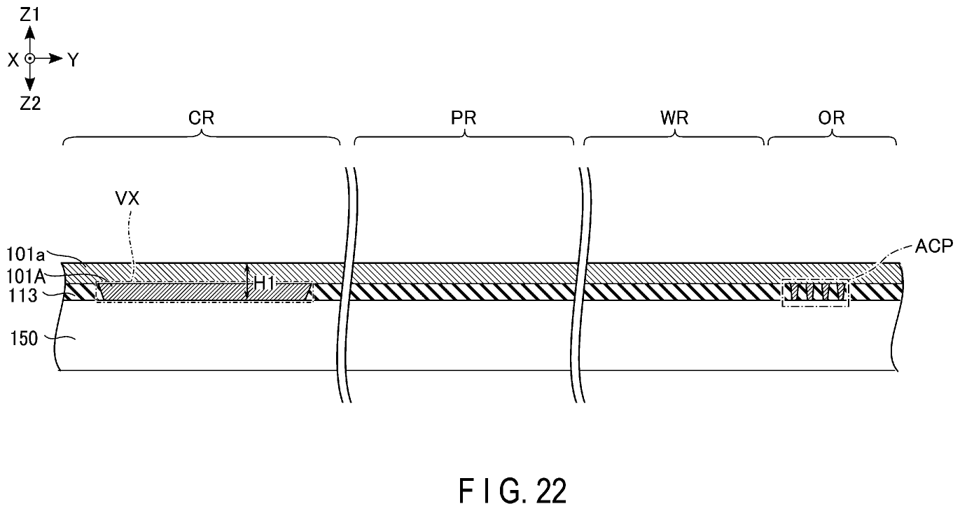

FIGS. 21 and 22 are cross-sectional views each showing an exemplary cross-sectional structure of the memory device according to the modification of the first embodiment in the course of manufacturing. FIGS. 21 and 22 respectively correspond to FIGS. 12 and 13 in the first embodiment.

First, in the same manner as in the first embodiment, the insulating layer 113 is formed on the upper surface of the semiconductor substrate 150 in the Z1 direction. Thereafter, the insulating layer 113 is processed such that grooves corresponding to the protruding portions ACP are formed in the circumferential region OR and a hole corresponding to the protruding portion VX is formed in the core region CR.

Next, as illustrated in FIG. 21, with the silicon that has grown from the semiconductor substrate 150 through epitaxy, the conductive layer 101A may be embedded in the hole formed in the core region CR and grooves formed in the circumferential region OR. As a result, protruding portions VX and ACP are formed.

Thereafter, as illustrated in FIG. 22, a conductive layer 101a is formed on the upper surfaces of the insulating layer 113 and conductive layer 101A in the Z1 direction. As previously mentioned, the conductive layer 101A has approximately the same thickness as that of the insulating layer 113. The flatness of the upper surface of the conductive layer 101a in the Z1 direction therefore will not be impaired even in the region where a protruding portion VX is provided. The total thickness of the conductive layer 101a and conductive layer 101A is controlled to be a predetermined thickness H1.

The subsequent steps of the manufacturing method are the same as those of the first embodiment, and therefore the description is omitted.

### 1.4.3 Effects of Modification of First Embodiment

According to the modification of the first embodiment, the conductive layers 101 and 101A are formed to be discontinuous films. In order to form the conductive layer 101A from the same material as that of the conductive layer 101 to exhibit film properties different from those of the conductive layer 101, silicon is grown through epitaxy from the semiconductor substrate 150. In this manner, unevenness in the surface on which the conductive layer 101a is formed can be suppressed. This makes it unnecessary to perform CMP in the formation of the conductive layer 101a.

### 2. Second Embodiment

A memory device according to a second embodiment will be described next. The second embodiment differs from the first embodiment in that protruding portions are also formed in the peripheral circuit region PR and wall region WR. The following description will basically focus on aspects of the structure and manufacturing method that differ from the first embodiment. Portions of the structure and manufacturing method similar to those of the first embodiment may be omitted from the description.

### 2.1 Cross-Sectional Structure of Memory Device

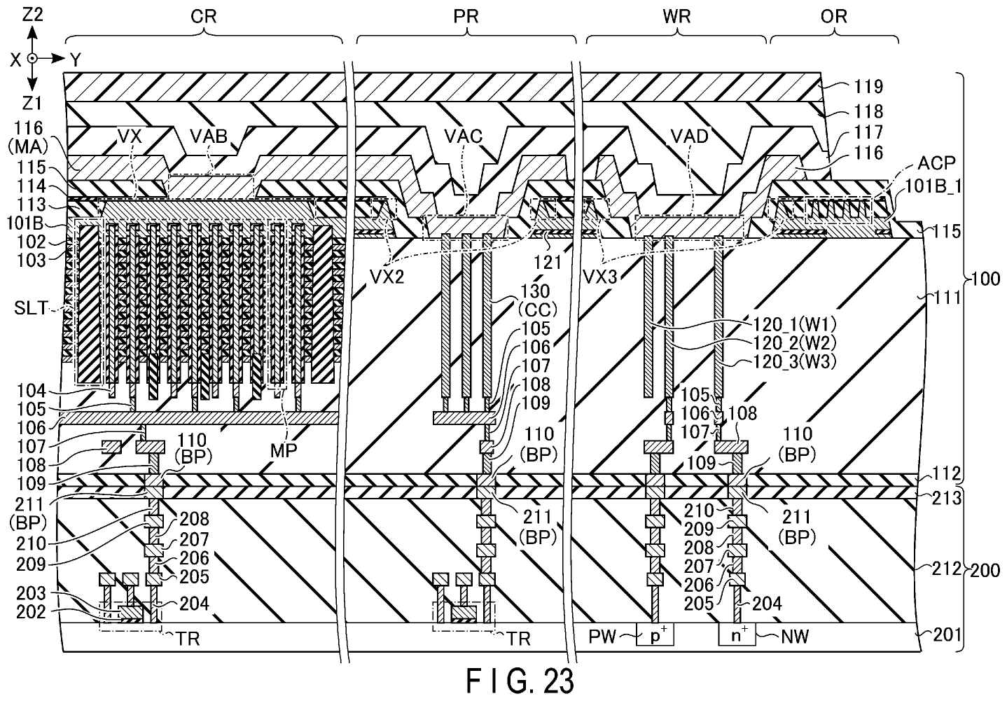

FIG. 23 is a cross-sectional view showing an exemplary cross-sectional structure of a memory device according to the second embodiment. FIG. 23 corresponds to the structure of FIG. 5 in the first embodiment.

As illustrated in FIG. 23, the memory device 3 according to the second embodiment includes a conductive layer 101B in place of the conductive layer 101. The conductive layer 101B extends in the X direction and Y direction. The conductive layer 101B in the core region CR serves as a source line SL. The conductive layer 101B may contain silicon as a semiconductor. In the core region CR, the insulating layers 102 and interconnect layers 103 are alternately stacked on the upper surface of the conductive layer 101B in the Z1 direction.

The conductive layer 101B in the core region CR includes a protruding portion VX having a certain thickness in the Z2 direction at a position overlapping the memory pillars MP when viewed in the Z direction. The conductive layer 101B in the peripheral circuit region PR includes protruding portions VX2. The conductive layer 101B in the wall region WR includes protruding portions VX3. An insulating layer 113 is deposited on the upper surface of the conductive layer 101B in the Z2 direction, where the protruding portions VX, VX2, or VX3 are not arranged. The protruding portions VX2 and VX3 have a thickness approximately the same as that of the protruding portion VX and of the insulating layer 113.

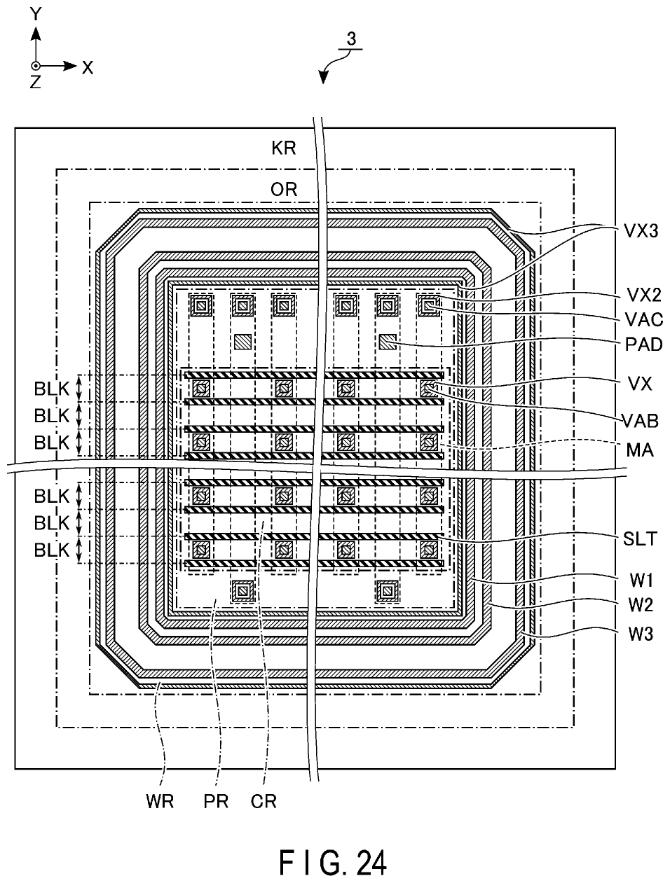

FIG. 24 is a plan view showing an exemplary planar layout of wall structures and connection wirings between the core region and peripheral circuit region in the memory device according to the second embodiment. FIG. 24 corresponds to the structure of FIG. 6 in the first embodiment. The members SLT, protruding portions VX, VX2, and VX3, connection portions VAB and VAC, external connection pad portions PAD, and wall structures W1 to W3 are hatched in FIG. 24.

As illustrated in FIG. 24, the protruding portion VX2 surrounds the connection portion VAC when viewed in the Z direction. The protruding portions VX3 surround the wall structures W1 to W3 as well as the connection portion VAD, which is not shown, when viewed in the Z direction. The portion of the protruding portion VX3 that is located outside the wall structures W1 to W3 is separated from the portion thereof that is located inside. The portion of the protruding portion VX3 located outside the wall structures W1 to W3 corresponds to the conductive layer 101B_1.

### 2.2 Manufacturing Method

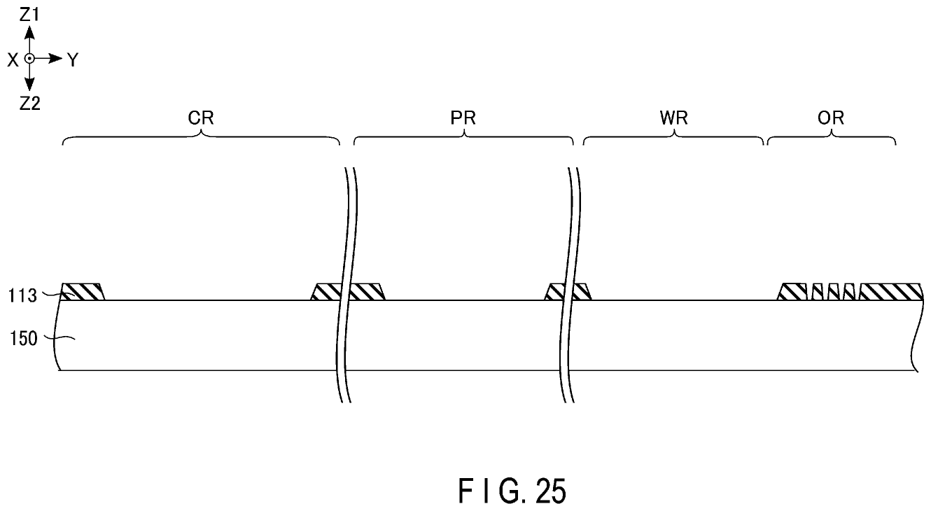

FIGS. 25 to 28 are cross-sectional views each showing an exemplary cross-sectional structure of the memory device according to the second embodiment in the course of manufacturing. FIGS. 25 to 28 respectively correspond to FIGS. 11 to 13 and 16 in the first embodiment.

First, an insulating layer 113 is formed on the upper surface of the semiconductor substrate 150 in the Z1 direction, as illustrated in FIG. 25. Thereafter, the insulating layer 113 is processed so as to form a hole corresponding to the protruding portion VX in the core region CR, a hole corresponding to the protruding portions VX2 in the peripheral circuit region PR, a groove corresponding to the protruding portions VX3 in the wall region WR, and grooves corresponding to the protruding portions ACP in the circumferential region OR at the same time. The diameters of the holes corresponding to the protruding portions VX and VX2 and the width of the groove corresponding to the protruding portions VX3 are larger than the width of a groove corresponding to a protruding portion ACP.

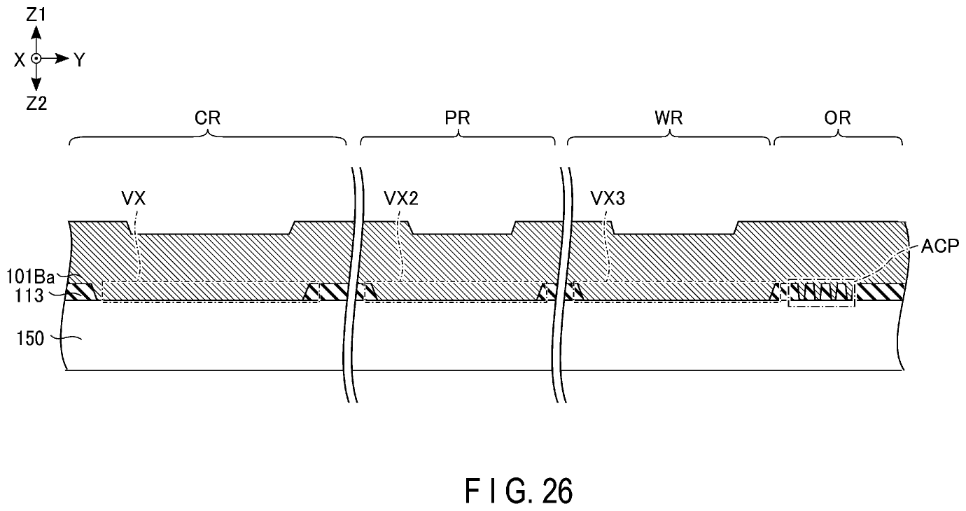

Next, as illustrated in FIG. 26, a conductive layer 101Ba is formed, for example, through the CVD. During this process, the holes corresponding to the protruding portions VX and VX2 and the grooves corresponding to the protruding portions VX3 and ACP are filled in. As a result, the protruding portions VX, VX2, VX3, and ACP are formed to be in contact with the semiconductor substrate 150. As previously mentioned, the diameters of the holes corresponding to the protruding portions VX and VX2 and the width of the groove corresponding to the protruding portions VX3 are significantly large with respect to the thickness of the conductive layer 101Ba. This may impair the flatness of the upper surface of the conductive layer 101Ba in the Z1 direction, where the protruding portions VX, VX2, and VX3 are to be formed.

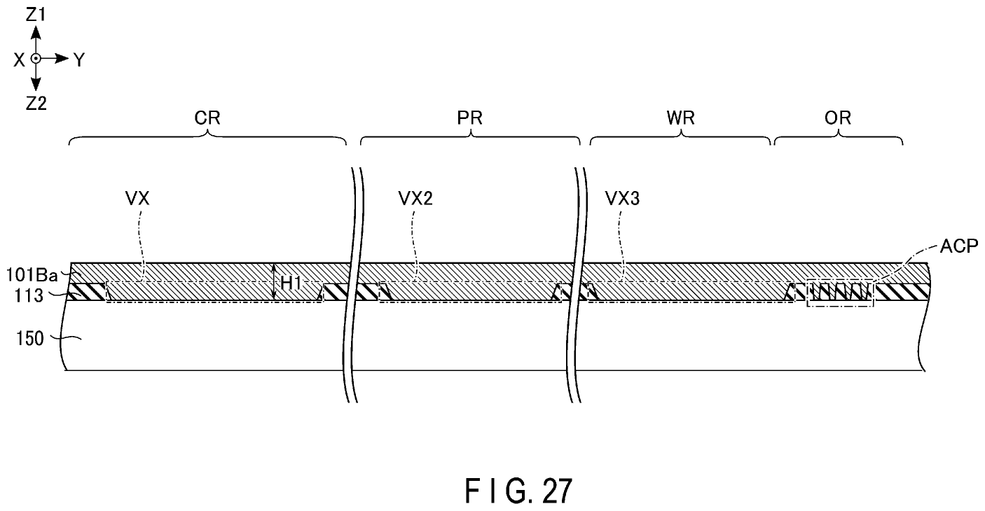

For the above reason, the conductive layer 101Ba is processed so as to planarize its Z1 direction-side upper surface, as illustrated in FIG. 27. For instance, after polishing the conductive layer 101Ba through the CMP until the insulating layer 113 is exposed, the conductive layer 101Ba may be additionally formed. Alternatively, the conductive layer 101Ba may be polished through blind CMP to a degree that the insulating layer 113 will not be exposed. In either case, the portion of the conductive layer 101Ba having the protruding portion VX is controlled to have a predetermined thickness H1.

Thereafter, a memory chip 100 is formed by the same step as in the first embodiment shown in FIG. 14. By the same step as in the first embodiment shown in FIG. 15, the memory chip 100 is bonded to the circuit chip 200.

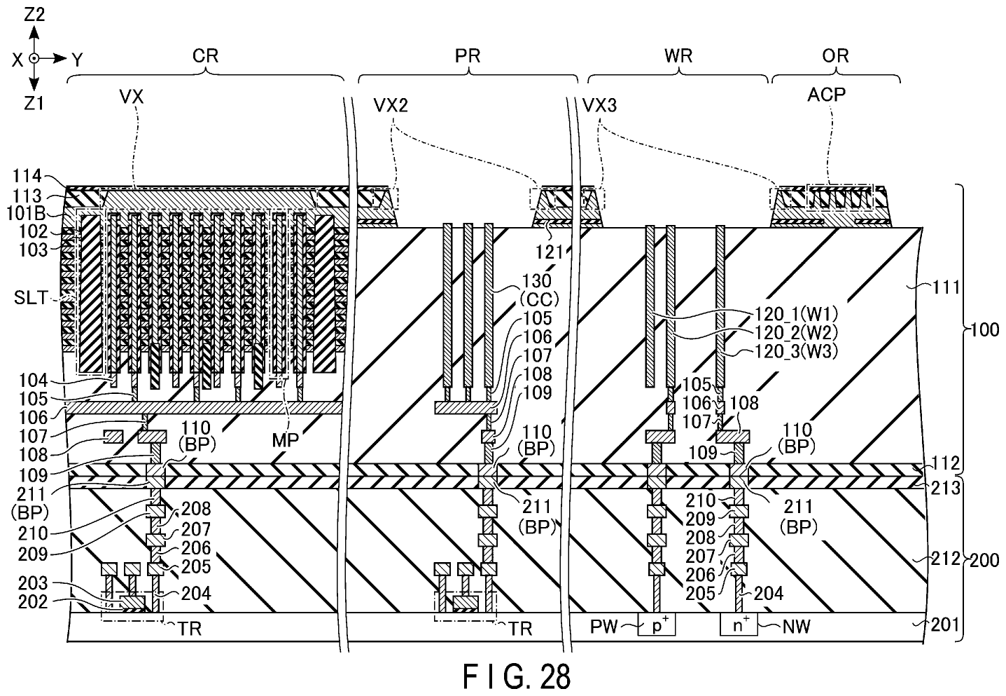

After the semiconductor substrate 150 is removed from the memory chip 100, an insulating layer 114 is formed in such a manner as to cover the insulating layer 113 and the protruding portions VX, VX2, VX3, and ACP, as illustrated in FIG. 28. Subsequently, the insulating layer 114, as well as the conductive layer 101B that includes the insulating layer 121, is processed so as to form a hole in the peripheral circuit region PR and a groove in the wall region WR together. In the circumferential region OR and kerf region KR, the peripheral portion outside the protruding portions ACP is removed. The hole formed in the peripheral circuit region PR corresponds to the region in which the connection portion VAC is to be formed. The groove formed in the wall region WR corresponds to the region in which the connection portion VAD is to be formed. In this manner, the conductors 130 are exposed in the hole formed in the peripheral circuit region PR, and the conductors 120_1 to 120_3 are exposed in the groove formed in the wall region WR.

The subsequent steps of the manufacturing method are the same as those of the first embodiment, and therefore the description is omitted.

### 2.3 Effects of Second Embodiment

According to the second embodiment, the protruding portions VX2 and VX3 are provided in the regions of the conductive layers 101B and 101B_1 corresponding to the connection portions VAC and VAD. The protruding portions VX2 and VX3 have a thickness approximately the same as that of the insulating layer 113. Thus, the insulating layer 113 in the hole corresponding to the connection portion VAC and the groove corresponding to the connection portion VAD can be replaced with silicon. The conductive layer 101B can be thereby removed from the region in which the hole corresponding to the connection portion VAC and the groove corresponding to the connection portion VAD are formed, without processing the insulating layer 113. In this manner, the time for the processing can be shortened.

### 2.4 Modification of Second Embodiment

In the second embodiment, the conductive layer 101B has been described as a continuous film that includes a protruding portion VX, which is not a limitation. The protruding portion VX may be formed to have film properties different from those of the remaining portion of the conductive layer 101B, or formed from a material different from that of the remaining portion. The following description will basically focus on aspects of the structure and manufacturing method that differ from the second embodiment. Portions of the structure and manufacturing method similar to those of the second embodiment may be omitted from the description.

### 2.4.1 Cross-Sectional Structure of Memory Device

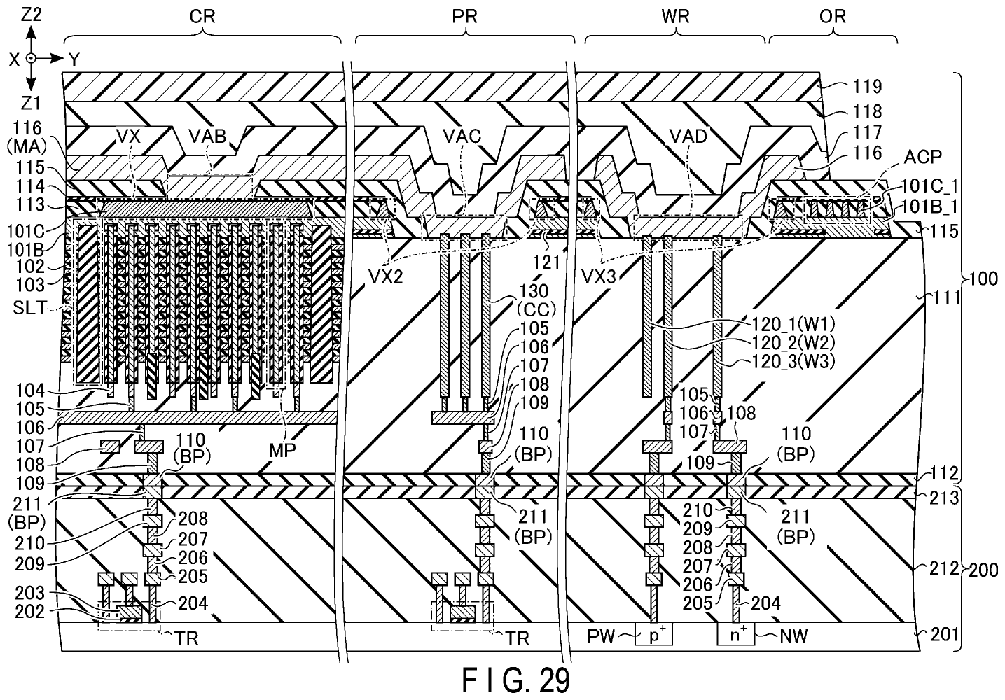

FIG. 29 is a cross-sectional view showing an exemplary cross-sectional structure of a memory device according to a modification of the second embodiment. FIG. 29 corresponds to the structure of FIG. 23 in the second embodiment.

As illustrated in FIG. 29, the conductive layer 101B does not include protruding portions VX, VX2, or VX3. A conductive layer 101C of approximately the same thickness as that of the insulating layer 113 is deposited on the upper surface of the conductive layer 101B in the Z2 direction so as to function as the protruding portions VX, VX2, and VX3.

The conductive layer 101C may be formed of a different material from that of the conductive layer 101B, such as a metal. If the material of the conductive layer 101C differs from that of the conductive layer 101B, the conductive layer 101C may contain copper or tungsten. The conductive layer 101C may have film properties that differ from those of the conductive layer 101B. If the conductive layer 101C differs from the conductive layer 101B in film properties, the conductive layer 101C may contain silicon. The crystalline size, for example, of the silicon in the conductive layer 101C differs from that of the silicon in the conductive layer 101B.

For the above reason, when the conductive layer 101B and conductive layer 101C differ from each other in materials or film properties, the boundary between the conductive layer 101B and conductive layer 101C can be visually recognized. That is, the conductive layers 101B and 101C are discontinuous films.

Similarly, the conductive layer 101B_1 does not include protruding portions ACP. A conductive layer 101C_1 of approximately the same thickness as that of the insulating layer 113 is deposited on the upper surface of the conductive layer 101B_1 in the Z2 direction so as to function as the protruding portions ACP.

The conductive layer 101C_1 may be formed of a different material from that of the conductive layer 101B_1, such as a metal. If the material of the conductive layer 101C_1 differs from that of the conductive layer 101B_1, the conductive layer 101C_1 may contain copper or tungsten. The conductive layer 101C_1 may have film properties that differ from those of the conductive layer 101B_1. If the conductive layer 101C_1 differs from the conductive layer 101B_1 in film properties, the conductive layer 101C_1 may contain silicon. The crystalline size, for example, of the silicon in the conductive layer 101C_1 differs from that of the silicon in the conductive layer 101B_1.

For the above reason, when the conductive layer 101B_1 and conductive layer 101C_1 differ from each other in materials or film properties, the boundary between the conductive layer 101B_1 and conductive layer 101C_1 can be visually recognized. That is, the conductive layers 101B_1 and 101C_1 are discontinuous films.

### 2.4.2 Manufacturing Method

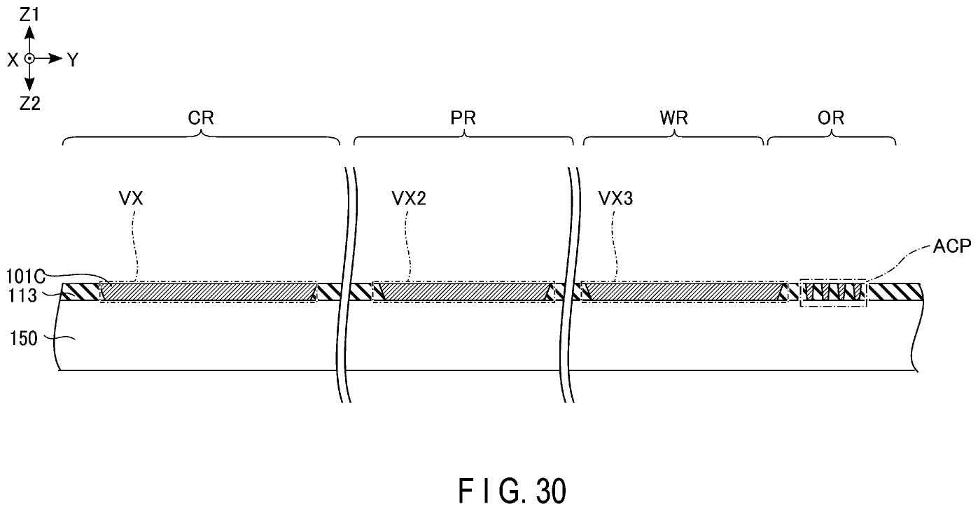

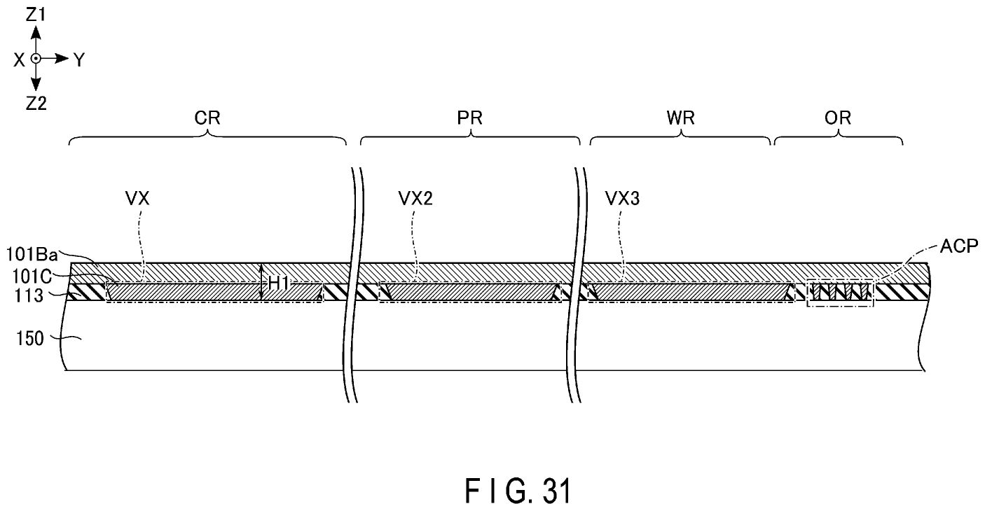

FIGS. 30 and 31 are cross-sectional views each showing an exemplary cross-sectional structure of the memory device according to the modification of the second embodiment in the course of manufacturing. FIGS. 30 and 31 respectively correspond to FIGS. 26 and 27 in the second embodiment.

First, in the same manner as in the second embodiment, the insulating layer 113 is formed on the upper surface of the semiconductor substrate 150 in the Z1 direction. Thereafter, the insulating layer 113 is processed so as to form a hole corresponding to the protruding portion VX in the core region CR, a hole corresponding to the protruding portions VX2 in the peripheral circuit region PR, a groove corresponding to the protruding portions VX3 in the wall region WR, and grooves corresponding to the protruding portions ACP in the circumferential region OR at the same time.

Next, as illustrated in FIG. 30, for example with the silicon that has been grown from the semiconductor substrate 150 through epitaxy, the holes formed in the core region CR and peripheral circuit region PR and grooves formed in the wall region WR and circumferential region OR are filled with the conductive layer 101C. The conductive layer 101C has approximately the same thickness as that of the insulating layer 113. As a result, the protruding portions VX, VX2, VX3, and ACP are formed.

Next, as illustrated in FIG. 31, a conductive layer 101Ba is formed on the upper surfaces of the insulating layer 113 and conductive layer 101C in the Z1 direction. As previously mentioned, the conductive layer 101C has approximately the same thickness as that of the insulating layer 113. The flatness of the upper surface of the conductive layer 101Ba in the Z1 direction therefore will not be impaired in the region where the protruding portions VX, VX2, and VX3 are provided. The total thickness of the conductive layer 101Ba and conductive layer 101C is controlled to be a predetermined thickness H1.

The subsequent steps of the manufacturing method are the same as those of the second embodiment, and therefore the description is omitted.

### 2.4.3 Effects of Modification of Second Embodiment

According to the modification of the second embodiment, the conductive layers 101B and 101C are formed to be discontinuous films. In order to deposit the conductive layer 101C of the same material as that of the conductive layer 101B but having film properties different from those of the conductive layer 101B, silicon is grown through epitaxy from the semiconductor substrate 150. In this manner, unevenness in the surface on which the conductive layer 101Ba is formed can be suppressed. This makes it unnecessary to perform CMP in the formation of the conductive layer 101Ba.

### 3. Third Embodiment

A memory device according to the third embodiment will be described next. The third embodiment differs from the first embodiment in the protruding portion of the core region CR that is formed by a fine pattern. The following description will basically focus on aspects of the structure and manufacturing method that differ from the first embodiment. Portions of the structure and manufacturing method similar to those of the first embodiment may be omitted from the description.

### 3.1 Cross-Sectional Structure of Memory Device

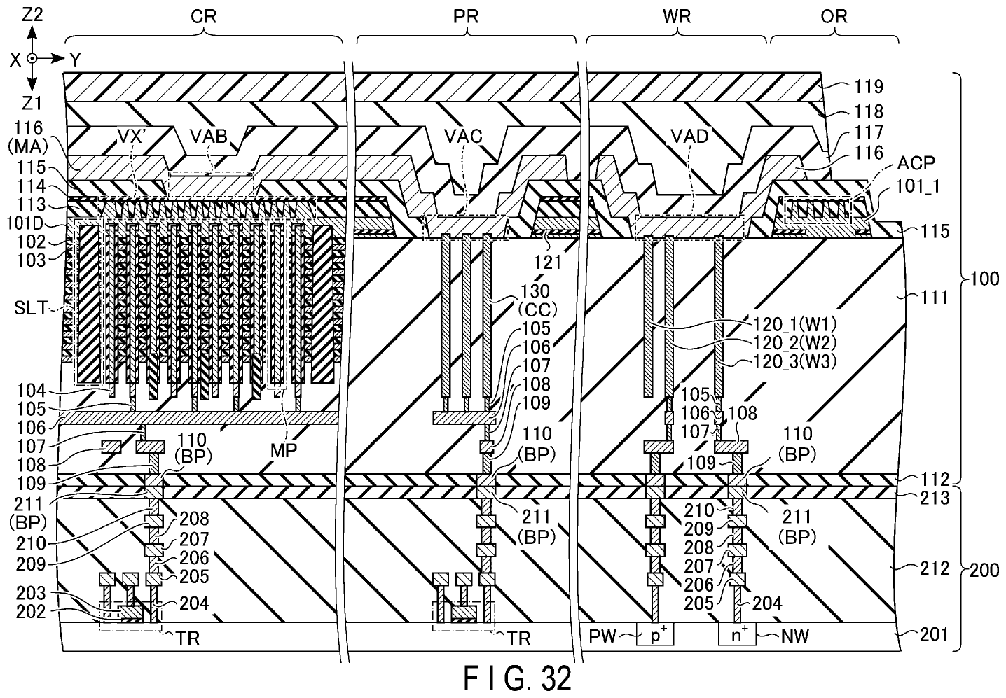

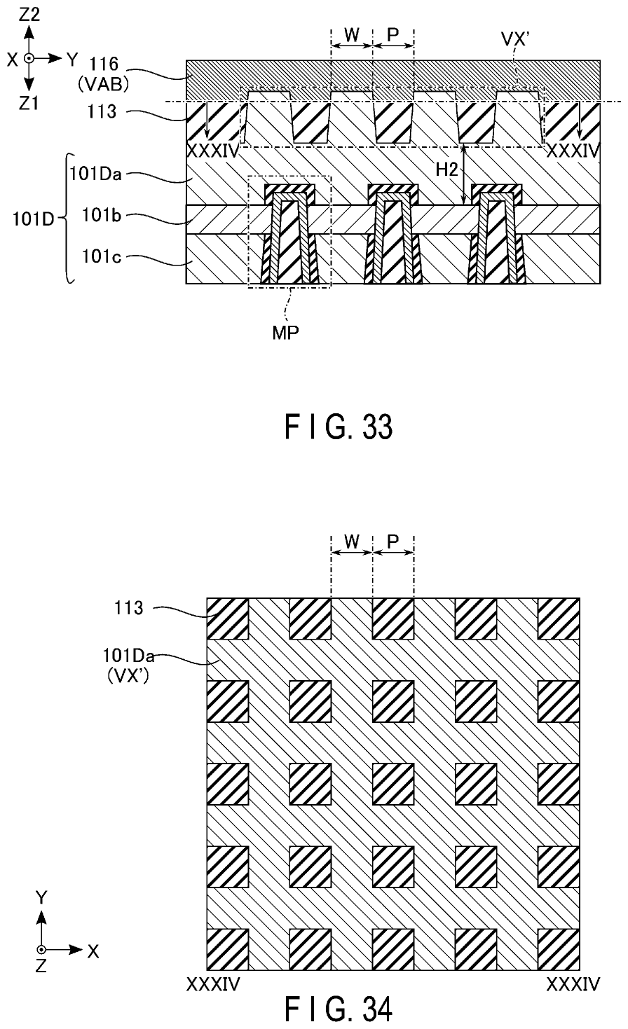

FIG. 32 is a cross-sectional view showing an exemplary cross-sectional structure of a memory device according to the third embodiment. FIG. 33 is a cross-sectional view showing an exemplary cross-sectional structure of a memory cell array in the memory device according to the third embodiment. FIG. 34 is a cross-sectional view of an exemplary pattern of a protruding portion in the memory cell array taken along line XXXIV-XXXIV of FIG. 33 in the memory device according to the third embodiment. FIG. 32 corresponds to the structure of FIG. 5 in the first embodiment. FIG. 33 corresponds to part of the conductive layer 101D illustrated in FIG. 32, which includes protruding portions VX′.

As illustrated in FIG. 32, a memory device 3 according to the third embodiment includes a conductive layer 101D in place of the conductive layer 101. The conductive layer 101D extends in the X direction and Y direction. The conductive layer 101D in the core region CR serves as a source line SL. The conductive layer 101D may contain silicon as a semiconductor. In the core region CR, the insulating layers 102 and interconnect layers 103 are alternately stacked on the upper surface of the conductive layer 101D in the Z1 direction.

As illustrated in FIG. 33, the conductive layer 101D in the core region CR includes three conductive layers 101Da, 101b, and 101c. The conductive layer 101b is deposited on the upper surface of the conductive layer 101Da in the Z1 direction. The conductive layer 101c is deposited on the upper surface of the conductive layer 101b in the Z1 direction. The conductive layer 101b is in contact with the semiconductor film 141 in the memory pillar MP.

The conductive layer 101Da includes protruding portions VX′ each having a certain thickness in the Z2 direction, at positions overlapping the memory pillars MP when viewed in the Z direction. An insulating layer 113 is deposited on the upper surface of the conductive layer 101Da in the Z2 direction, where no protruding portion VX′ is arranged. The thickness of a protruding portion VX′ is approximately the same as that of the insulating layer 113, or is larger than that of the insulating layer 113. The side surfaces of the protruding portion VX′ are tapered with its width decreasing in the Z2 direction. When the protruding portion VX′ has a thickness larger than the thickness of the insulating layer 113, the width of the upper surface of the protruding portion VX′ in the Z2 direction is smaller than the width of the protruding portion VX′ at a level of the upper surface of the insulating layer 113 in the Z2 direction.

The protruding portion VX′ has a grid pattern as shown in FIG. 34 when viewed in the Z direction. The width W of a trace of the protruding portion VX′ is not larger than twice the thickness H2 (W≤2×H2), which is a thickness of a portion of the conductive layer 101Da excluding the protruding portion VX′. The thickness H2 may be around 300 nanometers. The pitch P of traces of any two adjacent protruding portions VX′ is larger than the width W (P>W).

### 3.2 Manufacturing Method

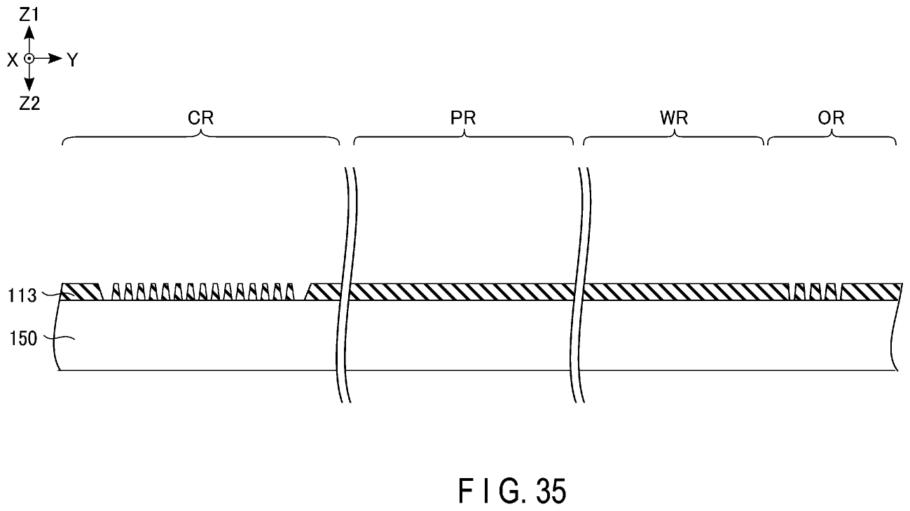

FIGS. 35 to 38 are cross-sectional views each showing an exemplary cross-sectional structure of the memory device according to the third embodiment in the course of manufacturing. FIGS. 35 to 38 respectively correspond to FIGS. 11, 13, 18, and 19 in the first embodiment.

First, an insulating layer 113 is formed on the upper surface of the semiconductor substrate 150 in the Z1 direction, as illustrated in FIG. 35. Thereafter, the insulating layer 113 is processed to form multiple holes corresponding to the protruding portions VX′ in the core region CR and grooves corresponding to the protruding portions ACP in the circumferential region OR at the same time. The diameter of a hole corresponding to a protruding portion VX′ may be approximately the same as the width of a groove corresponding to a protruding portion ACP.

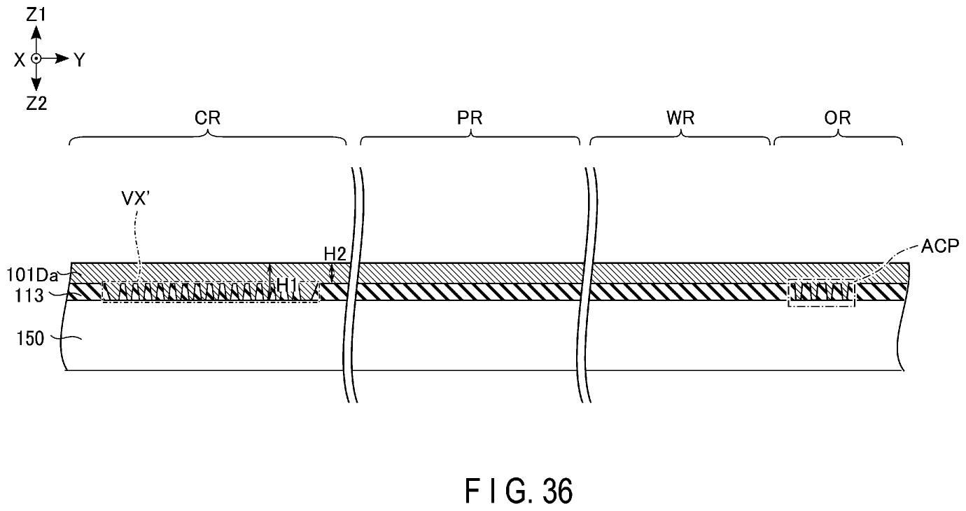

Next, as illustrated in FIG. 36, a conductive layer 101Da is formed, for example, through the CVD. During this process, the holes corresponding to the protruding portions VX′ and the grooves corresponding to the protruding portions ACP are filled in, thereby forming the protruding portions VX′ and ACP. The conductive layer 101Da is formed in such a manner that the thickness of its portion that includes the protruding portions VX′ becomes a predetermined thickness H1. The diameter of each hole corresponding to a protruding portion VX′ may be approximately the same as the thickness H2 of the conductive layer 101Da excluding the thickness of the protruding portion VX′. This can ensure the flatness of the upper surface of the conductive layer 101Da in the Z1 direction in the region where the protruding portions VX′ are provided.

Thereafter, a memory chip 100 is formed by the same step as in the first embodiment shown in FIG. 14. By the same step as in the first embodiment shown in FIG. 15, the memory chip 100 is bonded to the circuit chip 200. With the same process as in FIG. 16 of the first embodiment, the conductive layer 101Da and the insulating layers 113 and 114 are partially removed in the peripheral circuit region PR and wall region WR. With the same process as in FIG. 17 of the first embodiment, the insulating layer 115 is formed.

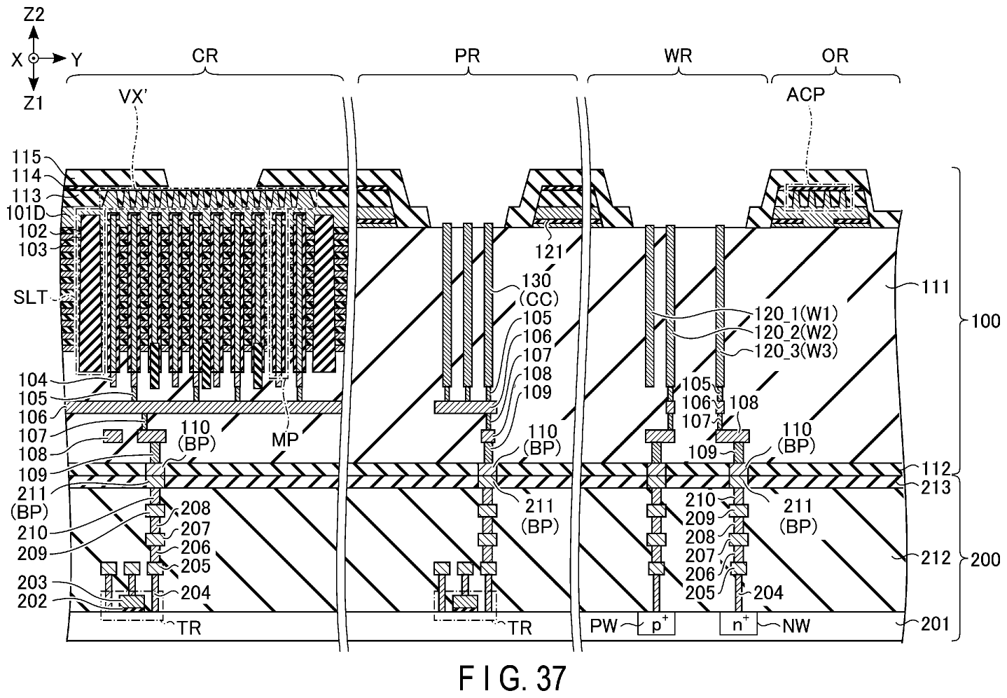

Next, as illustrated in FIG. 37, the insulating layers 114 and 115 are processed so as to form a hole in the core region CR and the peripheral circuit region PR and a groove in the wall region WR at the same time. The hole formed in the core region CR corresponds to the region in which the connection portion VAB is to be formed. The hole formed in the peripheral circuit region PR corresponds to the region in which the connection portion VAC is to be formed. The groove formed in the wall region WR corresponds to the region in which the connection portion VAD is to be formed. In this manner, the protruding portion VX′ is exposed in the hole formed in the core region CR, the conductors 130 are exposed in the hole formed in the peripheral circuit region PR, and the conductors 120_1 to 120_3 are exposed in the grooves formed in the wall regions WR.

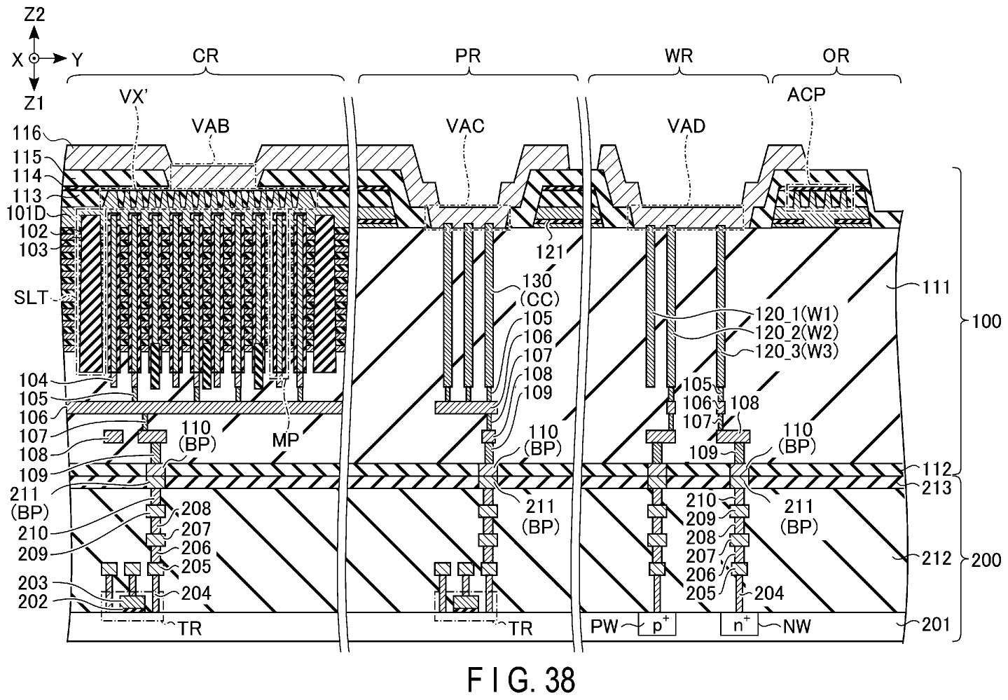

Next, the interconnect layer 116 is formed on the upper surface of the structure in the Z2 direction, as illustrated in FIG. 38. The holes formed in the core region CR and peripheral circuit region PR and the groove formed in the wall region WR are filled in with an interconnect layer 116. As a result, the connection portions VAB, VAC, and VAD are formed. Thereafter, the interconnect layer 116 is processed so as to separate the interconnect layer 116 in the core region CR and peripheral circuit region PR from the interconnect layer 116 in wall region WR. The interconnect layer 116 in the core region CR and peripheral circuit region PR is separated into several portions. Furthermore, a part of the interconnect layer 116 is removed from the kerf region KR and circumferential region OR.

Thereafter, the structure on the Z2 direction side of the interconnect layer 116 is formed. The memory device 3 is thereby completed.

### 3.3 Effects of Third Embodiment

According to the third embodiment, the protruding portions VX′ have a grid pattern when viewed in the Z direction. The width W of a trace of the protruding portion VX′ is not larger than twice the thickness H2 of a portion of the conductive layer 101Da excluding the thickness of the protruding portion VX′. Thus, when filling the holes corresponding to the protruding portions VX′ with the conductive layer 101Da, unevenness can be suppressed on the upper surface of the conductive layer 101Da in the Z1 direction. This makes it unnecessary to perform CMP in the formation of the conductive layer 101Da.

The pitch P of traces of any two adjacent protruding portions VX′ is larger than the width W. This can suppress deterioration of the coverage of the barrier metal of the interconnect layer 116 that tends to be caused by the unevenness of the protruding portions VX′ exposed at the time of forming a hole corresponding to the connection portion VAB. Thus, yield can be improved in manufacturing the memory device 3.

### 3.4 Modification of Third Embodiment

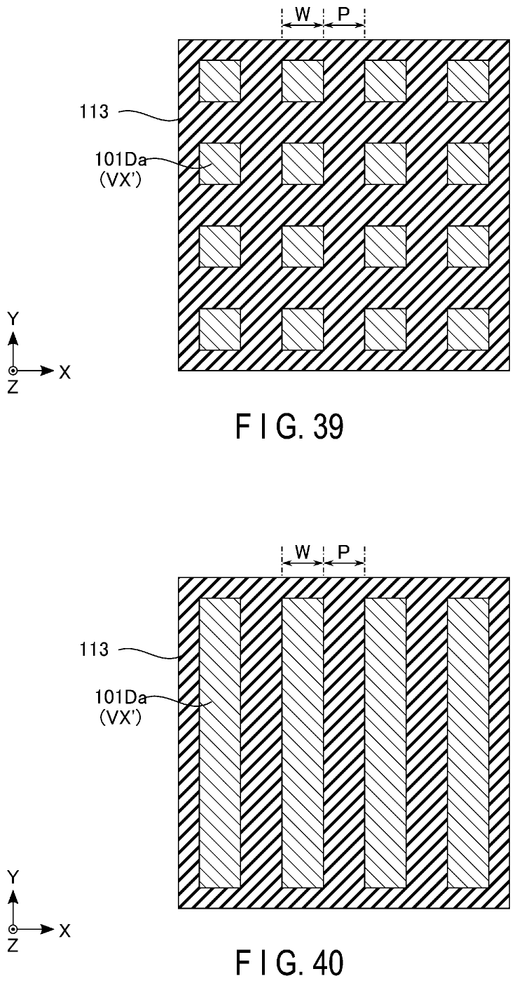

In the third embodiment, the protruding portion VX′ has been described as having a grid pattern, which is not a limitation. FIGS. 39, 40, and 41 are cross-sectional views for first to third examples, respectively, of the protruding portions in the memory cell array of the memory device according to modifications of the third embodiment.

The protruding portions VX′ may constitute a dotted pattern as illustrated in FIG. 39. In this case, the width W of a trace corresponds to the diameter of each dot, and the pitch P of traces corresponds to the distance between any two adjacent dots.

The protruding portions VX′ may constitute a pattern of lines as illustrated in FIG. 40. In this case, the width W of a trace corresponds to the width of each line, and the pitch P of the traces corresponds to the distance between any two adjacent lines.

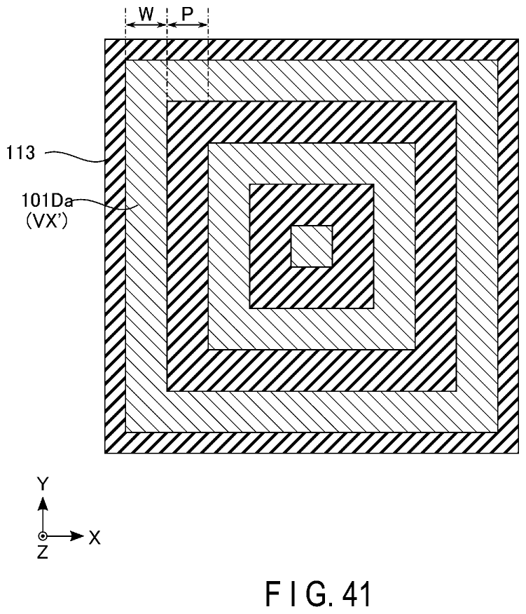

Further, the protruding portions VX′ may constitute a pattern as illustrated in FIG. 41, in which the traces are approximately concentric rings. In this case, the width W of a trace corresponds to the width of each ring, and the pitch P of the traces corresponds to the distance between any two adjacent rings.

In any case, the width W is designed to be not larger than twice the thickness H2 of a portion of the conductive layer 101Da excluding the protruding portions VX′. This can suppress deterioration of the flatness of the conductive layer 101Da in the region corresponding to the protruding portions VX′ at the time of forming the conductive layer 101Da on the semiconductor substrate 150. Furthermore, the pitch P is designed to be larger than the width W. This can suppress deterioration of the coverage of the barrier metal of the interconnect layer 116 that tends to be caused by the unevenness of the protruding portions VX′ exposed at the time of forming a hole corresponding to the connection portion VAB.

### 4. Others

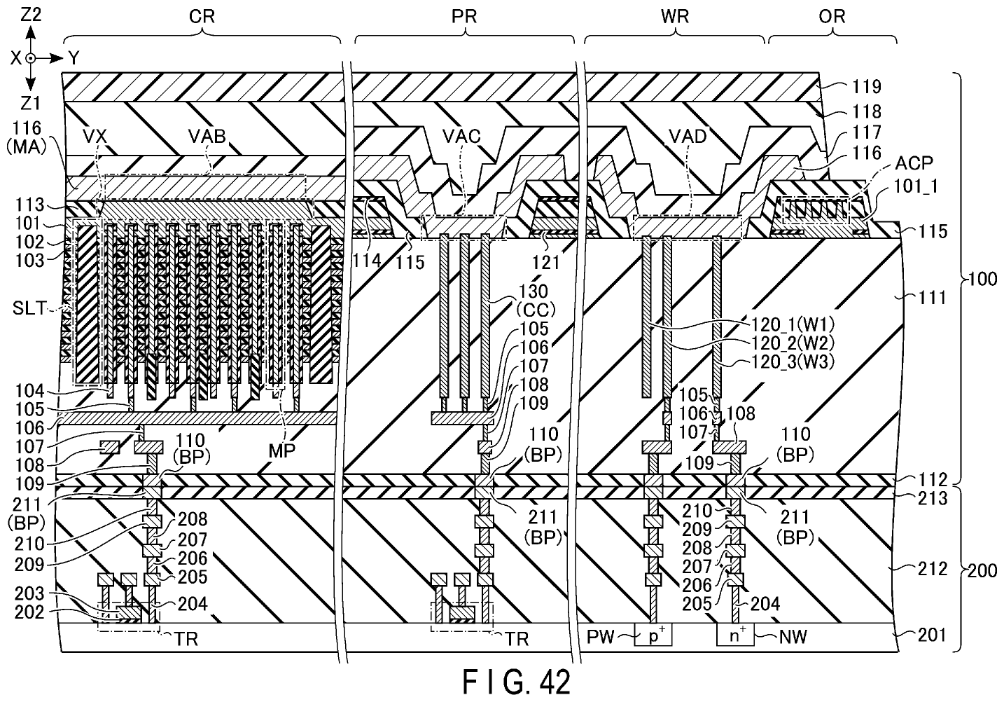

In the above first, second, and third embodiments, a portion of the insulating layer 115 corresponding to the protruding portion VX when viewed in the Z direction is opened at the time of simultaneously forming the connection portions VAB, VAC, and VAD, which is not a limitation. FIG. 42 is a cross-sectional view showing an exemplary cross-sectional structure of a memory device according to another modification. The insulating layer 115 in the core region CR may be entirely opened at the time of forming the connection portions VAB, VAC, and VAD, as illustrated in FIG. 42. Here, the interconnect layer 116 in the core region CR may be deposited at a uniform height in the Z direction, regardless of the connection portion VAB in contact with the protruding portion VX or any other portion that is not in contact with the protruding portion VX.

While certain embodiments have been described, these embodiments have been presented by way of example only, and are not intended to limit the scope of the invention. Indeed, the embodiments described herein may be embodied in a variety of other forms; furthermore, various omissions, substitutions and changes in the form of the embodiments described herein may be made without departing from the spirit of the inventions. The embodiments and modifications are included in the scope and spirit of the invention and are included in the scope of the claimed inventions and their equivalents.

What is claimed is:

1. A memory device comprising:
a first conductive layer;
a second conductive layer arranged with the first conductive layer in a first direction in a first region;
a plurality of third conductive layers arranged in the first region on a side opposite the first conductive layer in the first direction with respect to the second conductive layer in a mutually separated manner in the first direction;
a first conductor extending in the first direction and intersecting extensions of the third conductive layers in a second region different from the first region; and
a memory pillar extending in the first direction, of which portions intersecting the third conductive layers function as memory cells,
wherein the second conductive layer includes a first portion that extends in a plane intersecting the first direction and is in contact with an end portion of the memory pillar and a second portion that is arranged on a first surface of the first portion on a side of the first conductive layer in the first direction and protrudes with respect to the first portion, and
the first conductive layer includes a third portion in contact with the second portion in the first region and a fourth portion in contact with an end portion of the first conductor in the second region.

2. The memory device according to claim 1, wherein
the first conductive layer further includes a fifth portion in the first region, the fifth portion being positioned on a side opposite the second conductive layer in the first direction with respect to the third portion.

3. The memory device according to claim 1, wherein
the fourth portion is positioned on a side of the first portion of the second conductive layer in the first direction with respect to the third portion.

4. The memory device according to claim 1, wherein
the second portion is arranged at a position that overlaps the memory pillar when viewed in the first direction.

5. The memory device according to claim 1, wherein
a region of the second portion viewed in the first direction includes a region of the third portion viewed in the first direction.

6. The memory device according to claim 3, wherein
the end portion of the first conductor is positioned on a side of the third conductive layers in the first direction with respect to an extension of the first surface.

7. The memory device according to claim 1, wherein
the second conductive layer further includes a sixth portion different from the second portion, the sixth portion being arranged on the first surface and protruding with respect to the first portion, and
the sixth portion surrounds the fourth portion when viewed in the first direction.

8. The memory device according to claim 1, further comprising:
a second conductor extending in the first direction and intersecting the extensions of the third conductive layers; and
a fourth conductive layer arranged at a same level as the first conductive layer and separated from the first conductive layer,
wherein the fourth conductive layer includes a seventh portion in contact with an end portion of the second conductor and an eighth portion arranged on a side opposite the second conductor in the first direction with respect to the seventh portion.

9. The memory device according to claim 8, wherein
the end portion of the second conductor is positioned on a side of the third conductive layers in the first direction with respect to an extension of the first surface.

10. The memory device according to claim 8, wherein
the second conductor surrounds, when viewed in the first direction, the first conductive layer, the second conductive layer, the third conductive layers, and the memory pillar.

11. The memory device according to claim 8, further comprising:
a fifth conductive layer arranged at a same level as the second conductive layer and surrounding the second conductor when viewed in the first direction,
wherein the fifth conductive layer includes a ninth portion positioned at a same level as the first portion of the second conductive layer and a tenth portion arranged on a second surface of the ninth portion on a side of the first conductive layer in the first direction and protruding with respect to the ninth portion, and
a thickness of the tenth portion of the fifth conductive layer in the first direction is approximately the same as a thickness of the second portion of the second conductive layer in the first direction.

12. The memory device according to claim 11, wherein
the ninth portion of the fifth conductive layer includes:
an insulating sub-layer; and
a first conductive sub-layer and a second conductive sub-layer aligned in the first direction with the insulating sub-layer interposed, and
the first conductive sub-layer and the second conductive sub-layer are connected to each other through the insulating sub-layer.

13. The memory device according to claim 1, wherein
the memory pillar includes a semiconductor film extending in the first direction, and
the first portion of the second conductive layer includes:
a third conductive sub-layer in contact with the semiconductor film;
a fourth conductive sub-layer arranged between the third conductive sub-layer and the second portion of the second conductive layer; and
a fifth conductive sub-layer, the third conductive sub-layer being positioned between the fifth conductive sub-layer and the fourth conductive sub-layer.

14. The memory device according to claim 13, wherein
the second portion of the second conductive layer has a plurality of sub-portions that form a pattern, each of the sub-portions having a first width when viewed in the first direction and being arranged in a mutually separated manner at a first pitch, and
the first width is not larger than twice a thickness of the fourth conductive sub-layer.

15. The memory device according to claim 14, wherein
the first pitch is greater than the first width.

16. The memory device according to claim 1, wherein
the first portion of the second conductive layer includes a semiconductor.

17. The memory device according to claim 1, wherein
the first portion of the second conductive layer has the same material and film properties as the second portion of the second conductive layer.

18. The memory device according to claim 1, wherein
the first portion of the second conductive layer has different material or film properties from the second portion of the second conductive layer.

19. The memory device according to claim 1, wherein
the first conductive layer extends in a second direction within the first surface, and
the device further comprises a member that extends in a third direction and partitions the third conductive layers, the third direction intersecting the second direction within the first surface.

20. The memory device according to claim 1, further comprising:
a first electrode arranged on a side opposite the second conductive layer in the first direction with respect to the third conductive layers; and
a second electrode in contact with the first electrode,
wherein a first chip including the first conductive layer, the second conductive layer, the third conductive layers, the first conductor, the memory pillar, and the first electrode is bonded to a second chip including the second electrode, and
the memory pillar is positioned between the second conductive layer and the first electrode.
